(19) United States
(12) Patent Application Publication
(10) Pub. No.: US 2026/0293261 A1
(43) Pub. Date: Sep. 24, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Ming-Heng TSAI, Taipei (TW); Hong-Chih CHEN, Changhua County (TW); Jhon-Jhy LIAW, Zhudong Township (TW)

(73) Assignee: Taiwan Semiconductor Manufacturing Company, Ltd., Hsinchu (TW)

(21) Appl. No.: 19/082,567

(22) Filed: Mar. 18, 2025

(51) Int. Cl. H10D 64/23; H10D 30/00; H10D 84/01

(52) U.S. Cl. CPC H10D 64/256; H10D 30/501; H10D 64/254; H10D 84/013

(57) ABSTRACT

Semiconductor structures and methods for manufacturing the same are provided. The method includes nanostructures formed over a substrate, and a gate structure formed on the nanostructures. The semiconductor structure includes a source/drain (S/D) structure formed adjacent to the gate structure, and a first contact structure formed on a front-side of the S/D structure. The first contact structure includes a top portion with a top width, a middle portion with a middle width and a bottom portion with a bottom width, the top width is different from the middle width, and the middle width is different from the bottom width.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A-1 to 2P-1 illustrate cross-sectional representations of various stages of manufacturing the semiconductor structure shown along line A-A′ in FIG. 1E, in accordance with some embodiments.

FIGS. 2A-2 to 2P-2 illustrate cross-sectional representations of various stages of manufacturing the semiconductor structure shown along line B-B′ in FIG. 1E, in accordance with some embodiments.

FIG. 3 illustrates a cross-sectional view of a semiconductor structure, in accordance with some embodiments.

FIG. 4 illustrates a cross-sectional view of a semiconductor structure, in accordance with some embodiments.

FIGS. 5A-1 to 5D-1 illustrate cross-sectional representations of various stages of manufacturing a semiconductor structure shown along line A-A′ in FIG. 1E, in accordance with some embodiments.

FIGS. 5A-2 to 5D-2 illustrate cross-sectional representations of various stages of manufacturing the semiconductor structure shown along line B-B′ in FIG. 1E, in accordance with some embodiments.

FIG. 6A illustrates a cross-sectional view of a semiconductor structure, in accordance with some embodiments.

FIG. 6B illustrates a cross-sectional view of a semiconductor structure, in accordance with some embodiments.

FIGS. 7A-1 to 7C-1 illustrate cross-sectional representations of various stages of manufacturing a semiconductor structure shown along line A-A′ in FIG. 1E, in accordance with some embodiments.

FIGS. 7A-2 to 7C-2 illustrate cross-sectional representations of various stages of manufacturing the semiconductor structure shown along line B-B′ in FIG. 1E, in accordance with some embodiments.

FIG. 8 illustrates a cross-sectional view of a semiconductor structure, in accordance with some embodiments.

FIG. 9 illustrates a cross-sectional view of a semiconductor structure, in accordance with some embodiments.

FIGS. 10A-1 to 10C-1 illustrate cross-sectional representations of various stages of manufacturing a semiconductor structure shown along line A-A′ in FIG. 1E, in accordance with some embodiments.

FIGS. 10A-2 to 10C-2 illustrate cross-sectional representations of various stages of manufacturing the semiconductor structure shown along line B-B′ in FIG. 1E, in accordance with some embodiments.

FIGS. 11A-1 to 11C-1 illustrate cross-sectional representations of various stages of manufacturing a semiconductor structure shown along line A-A′ in FIG. 1E, in accordance with some embodiments.

FIGS. 11A-2 to 11C-2 illustrate cross-sectional representations of various stages of manufacturing the semiconductor structure shown along line B-B′ in FIG. 1E, in accordance with some embodiments.

FIG. 12 illustrates a cross-sectional view of a semiconductor structure, in accordance with some embodiments.

FIG. 13 illustrates a cross-sectional view of a semiconductor structure, in accordance with some embodiments.

FIG. 14 illustrates a cross-sectional view of a semiconductor structure, in accordance with some embodiments.

FIG. 15 illustrates a cross-sectional view of a semiconductor structure, in accordance with some embodiments.

FIG. 16 illustrates a cross-sectional view of a semiconductor structure, in accordance with some embodiments.

FIG. 17 illustrates a cross-sectional view of a semiconductor structure, in accordance with some embodiments.

FIG. 18A illustrates a cross-sectional view of a semiconductor structure, in accordance with some embodiments.

FIG. 18B illustrates a cross-sectional view of a semiconductor structure, in accordance with some embodiments.

FIG. 19 illustrates a cross-sectional view of a semiconductor structure, in accordance with some embodiments.

FIG. 20 illustrates a cross-sectional view of a semiconductor structure, in accordance with some embodiments.

FIG. 21 illustrates a cross-sectional view of a semiconductor structure 100o, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a number of nanostructures formed over a substrate. A gate structure formed over the nanostructures and an S/D structure adjacent to the gate structure. A front side S/D contact structure is formed on the S/D structure, and a portion of the front side S/D contact structure is embedded into the S/D structure. The front side S/D contact structure is formed by two step etching process to form an opening and a T-shaped or a V-shaped trench, and the materials formed in the opening and T-shaped trench or the V-shaped trench. Since the front side S/D contact structure is formed by two step etching process, the aspect ratio is recued to help the filling the contact materials. In addition, the contact area between the front side S/D contact structure and the S/D structure is increased by forming the front side S/D contact structure. The contact resistance between the front side S/D contact structure and the S/D structure is reduced. In addition, the back side contact structure is formed on back side of the S/D structure. The back side contact structure is used to connect to a power rail to reduce the area in the front side interconnect structure. Therefore, the performance of the semiconductor structure is improved. The source/drain (S/D) structures or S/D region(s) may refer to a source or a drain, individually or collectively dependent upon the context.”

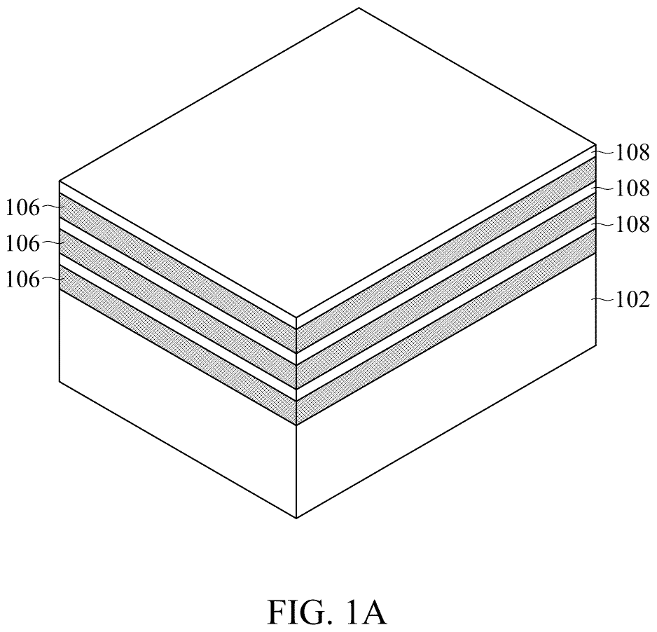

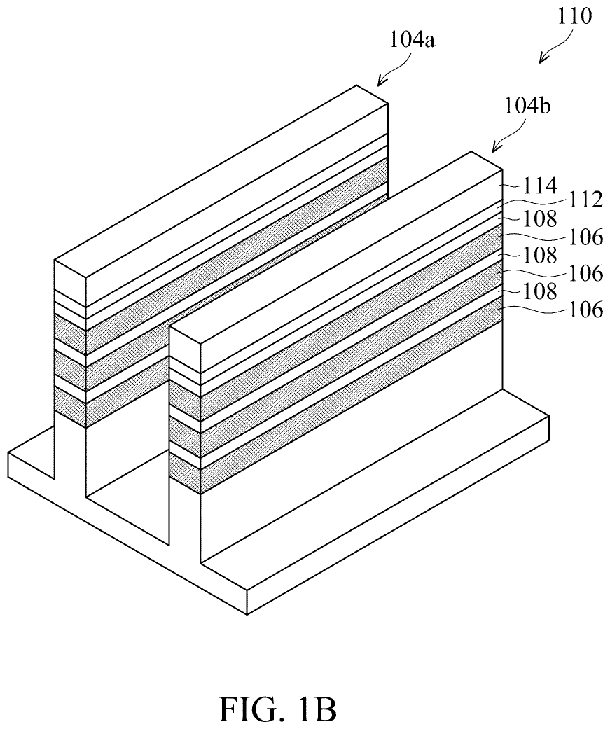

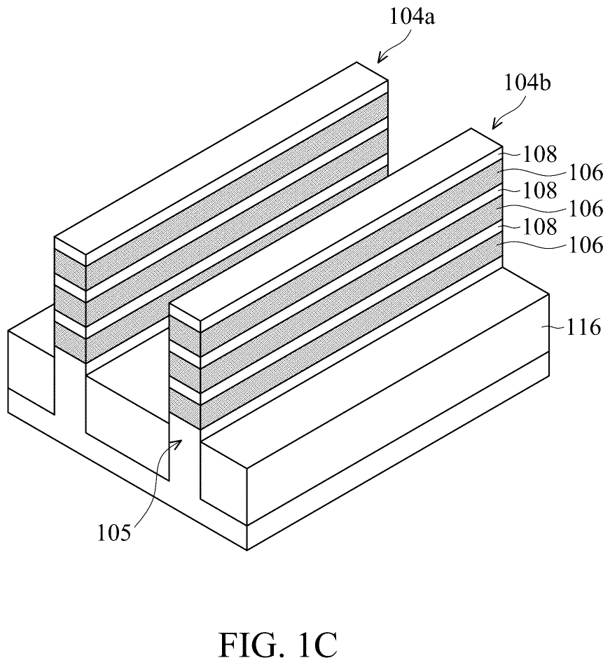

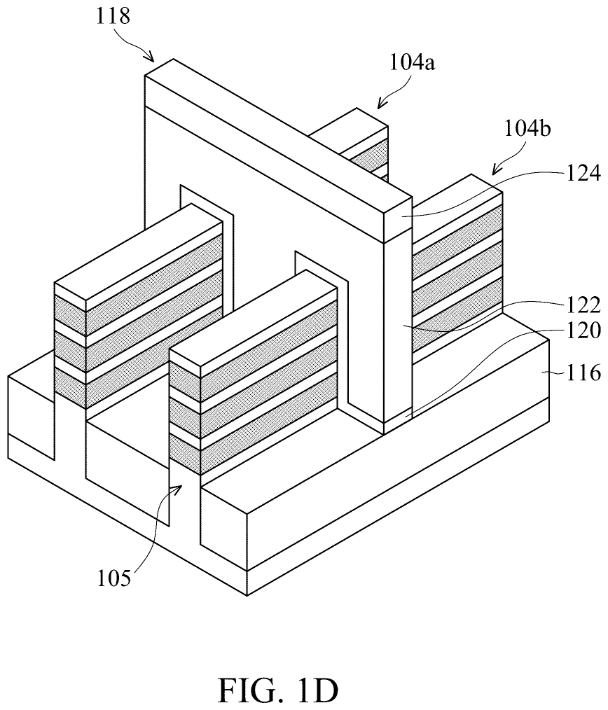

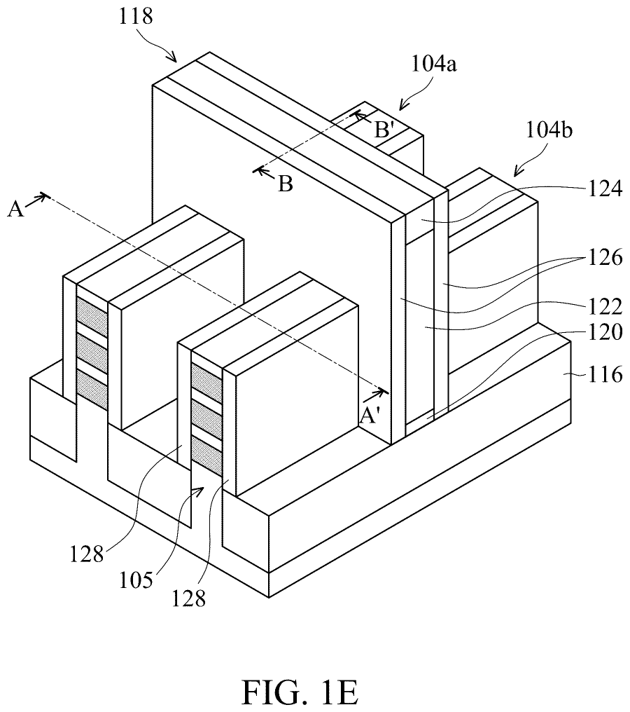

FIGS. 1A to 1E illustrate perspective views of intermediate stages of manufacturing a semiconductor structure 100a in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first stack structure 104a and a second stack structure 104b, in accordance with some embodiments. In some embodiments, each of the first stack structure 104a and a second stack structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

Next, as shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100 and is also referred to as shallow trench isolation (STI) feature in accordance with some embodiments.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, dummy gate structures 118 are formed across the fin structure 104 and extend over the isolation structure 116, in accordance with some embodiments. The dummy gate structures 118 may be used to define the source/drain regions and the channel regions of the resulting semiconductor structure 100.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

Next, as shown in FIG. 1E, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain structures from the dummy gate structure 118 and support the dummy gate structure 118, and the fin spacer layers 128 may be configured to constrain a lateral growth of subsequently formed source/drain structure and support the fin structure 104.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

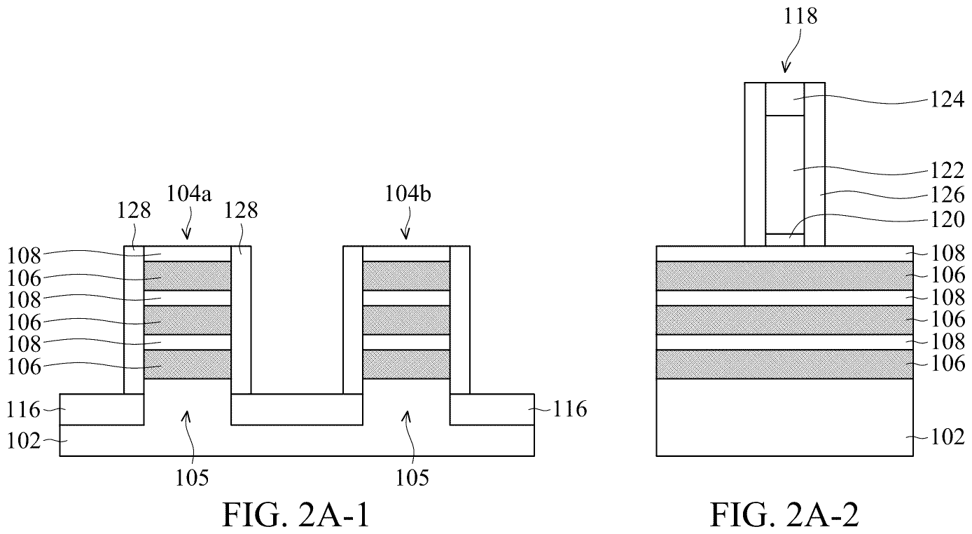

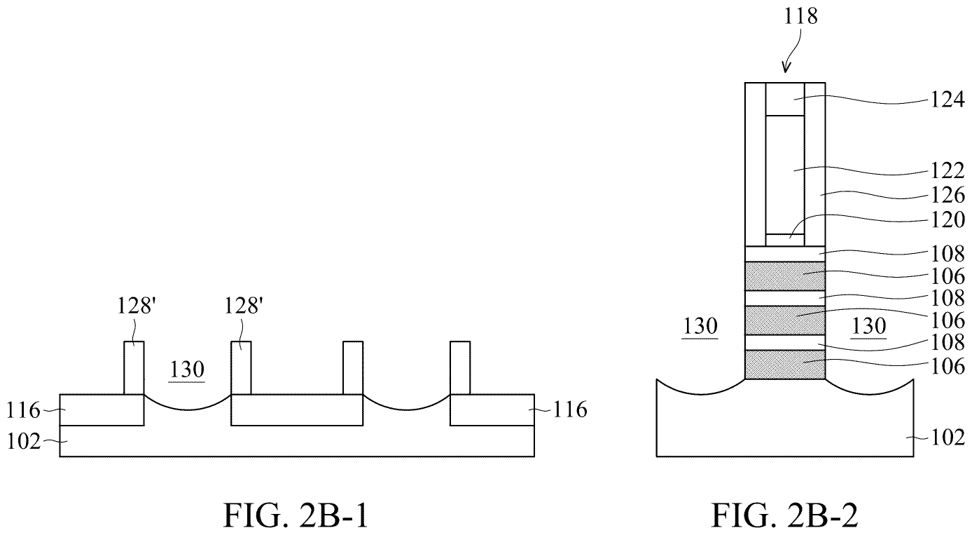

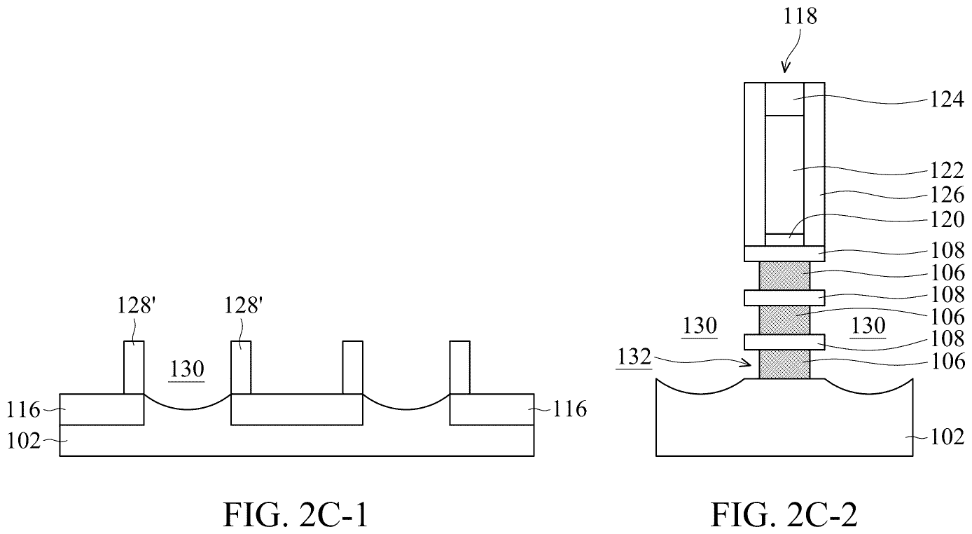

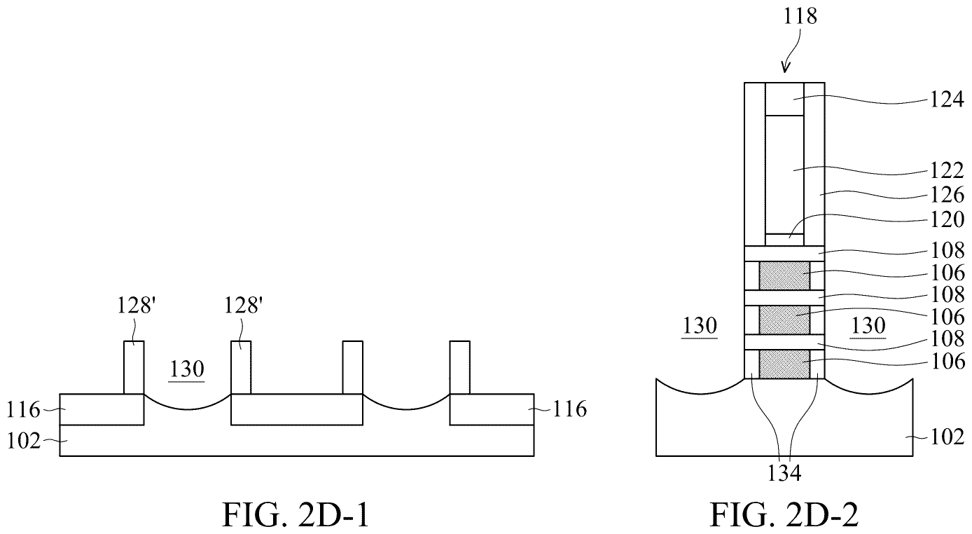

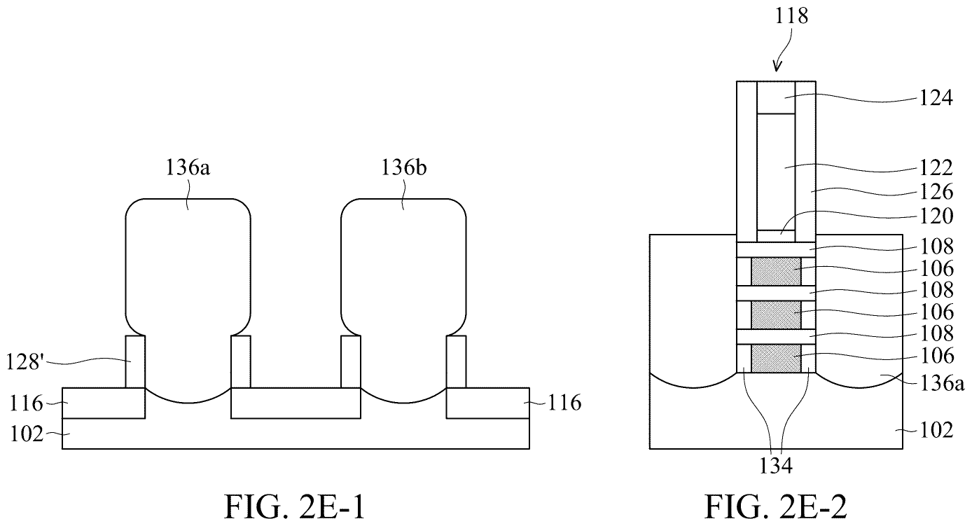

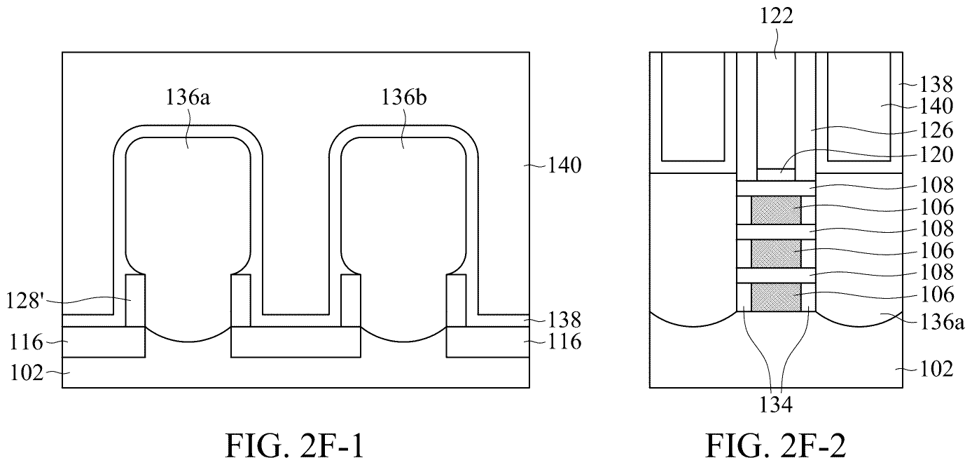

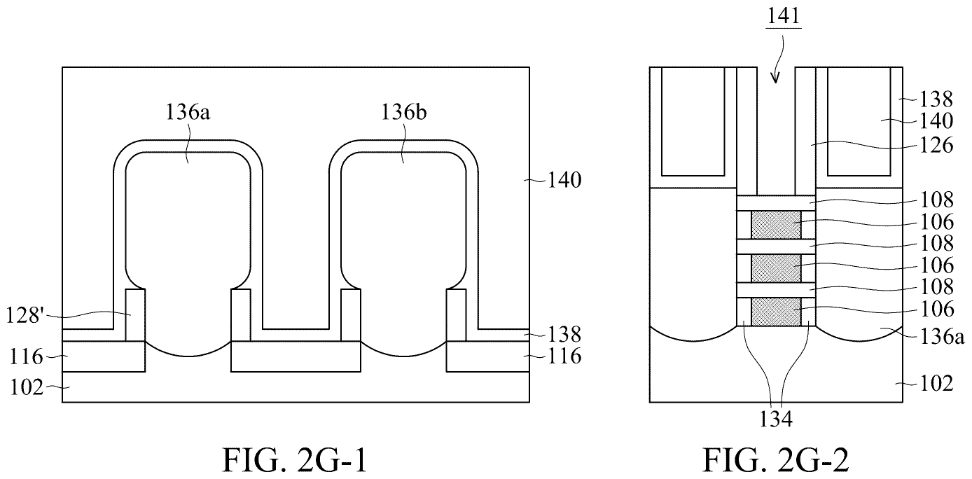

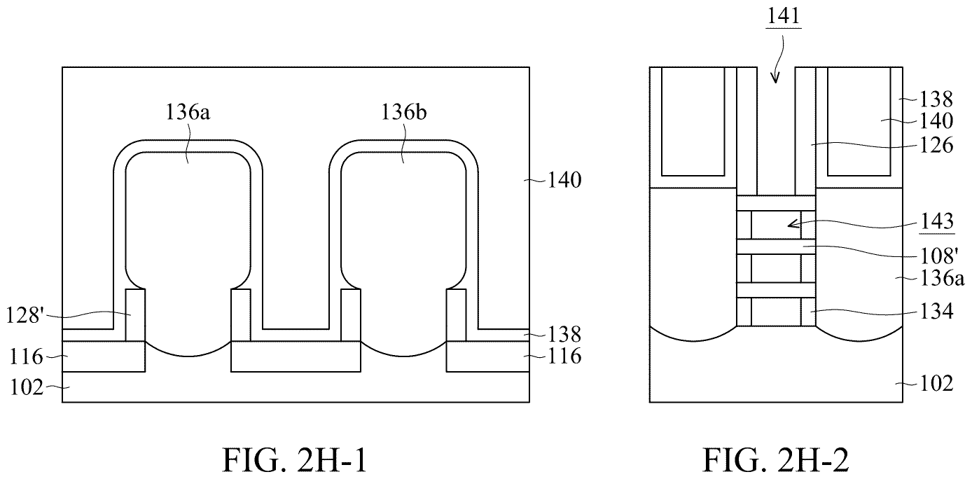

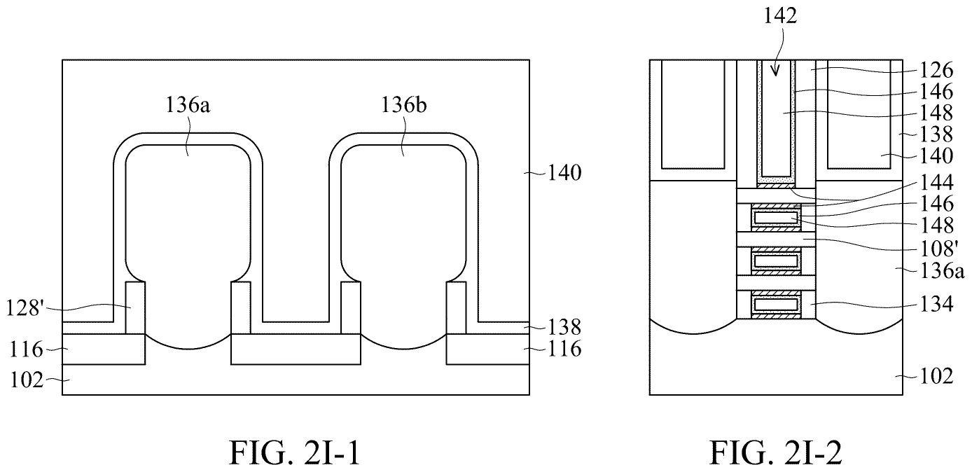

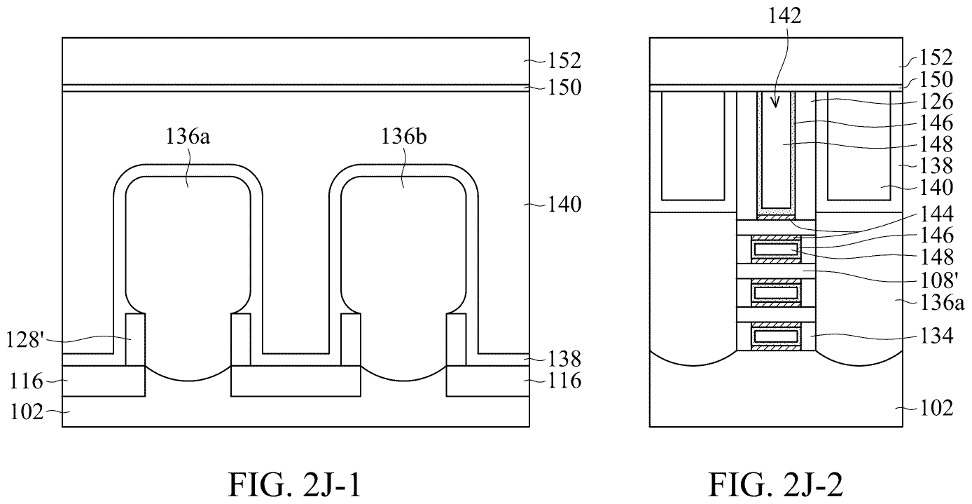

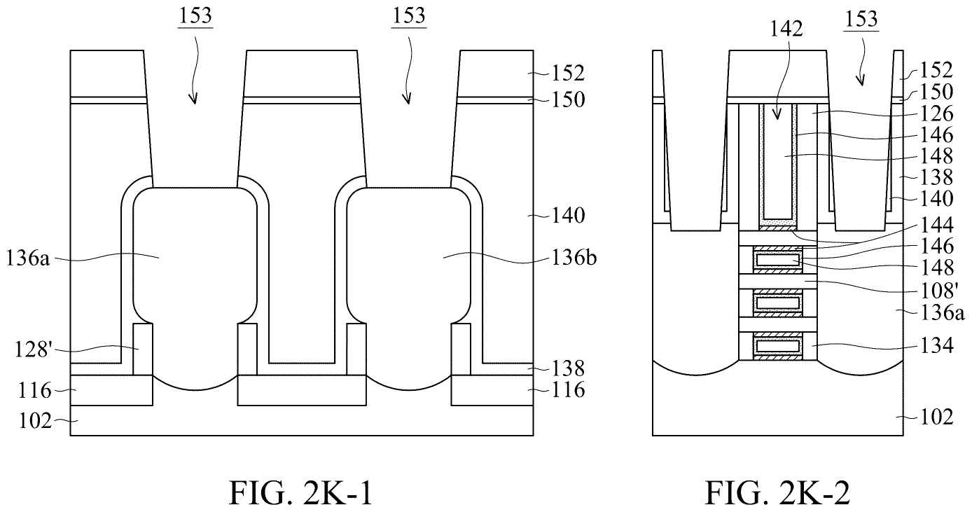

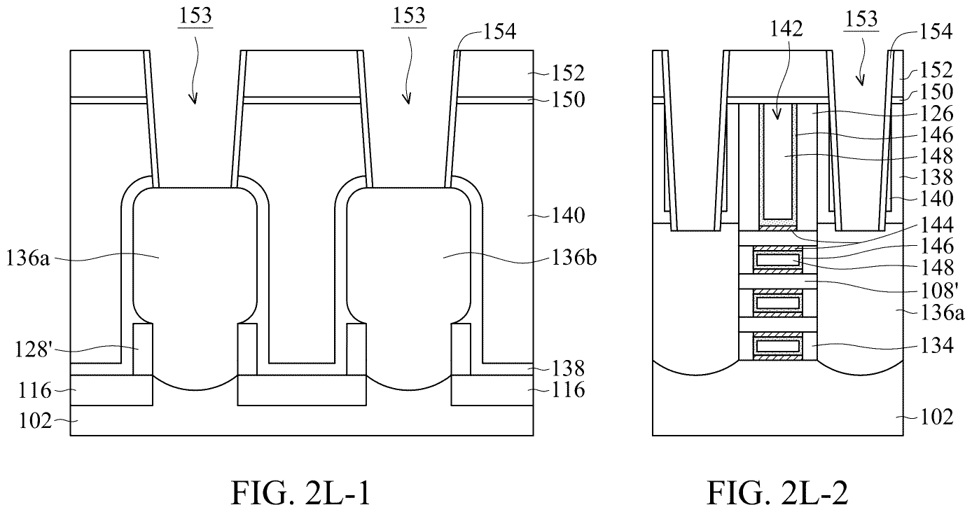

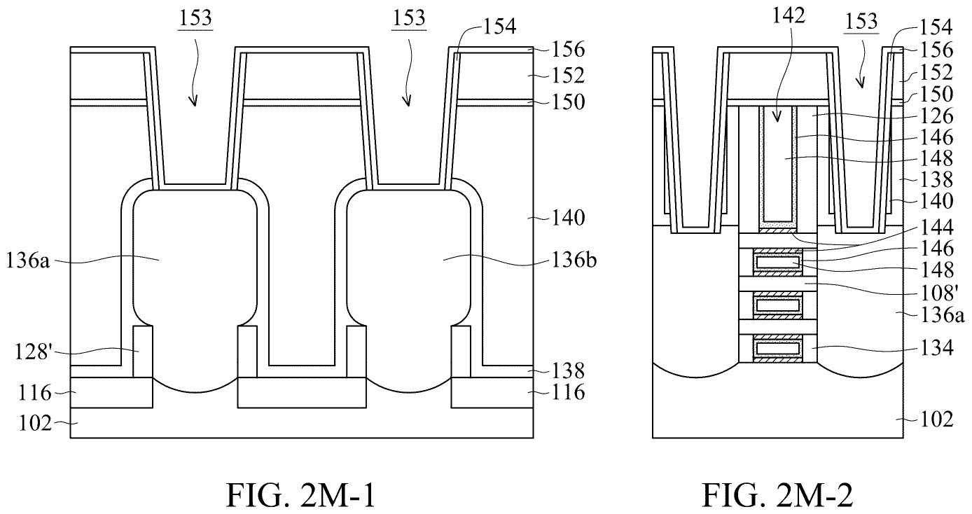

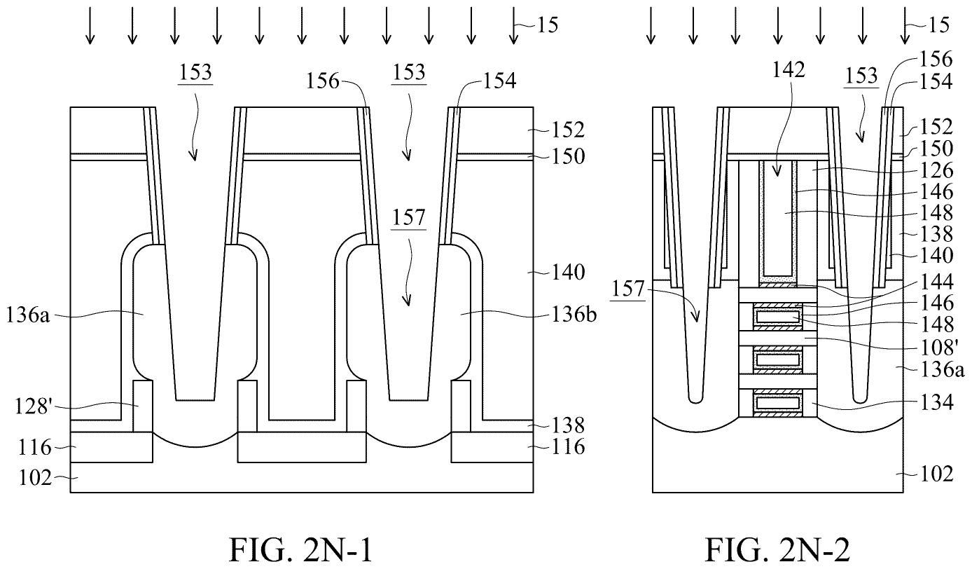

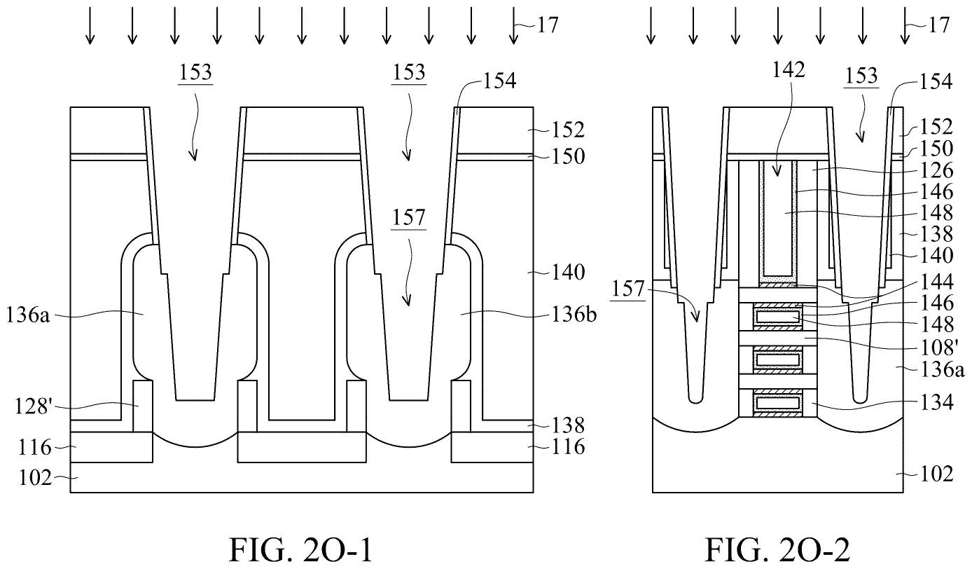

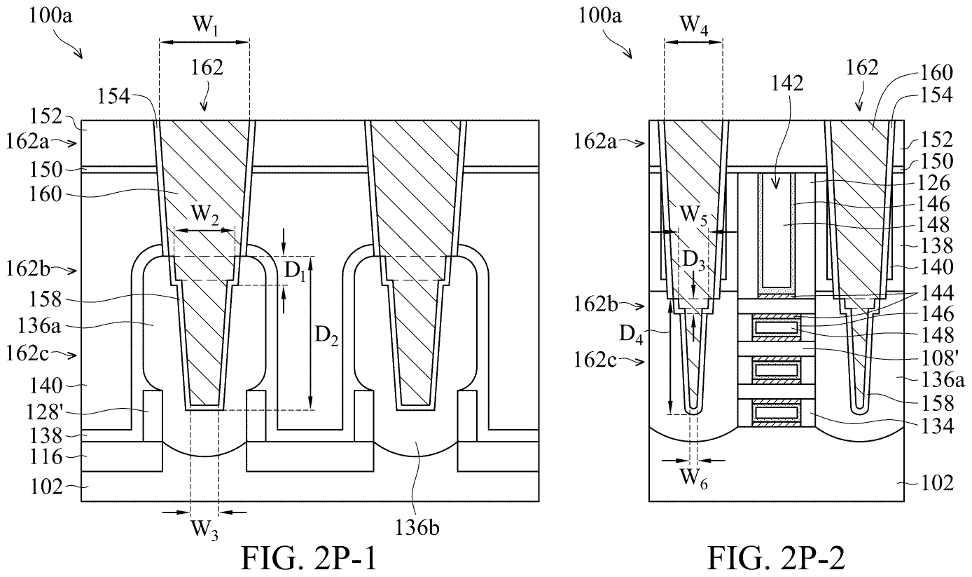

FIGS. 2A-1 to 2P-1 illustrate cross-sectional representations of various stages of manufacturing the semiconductor structure 100a shown along line A-A′ in FIG. 1E, in accordance with some embodiments. FIGS. 2A-2 to 2P-2 illustrate cross-sectional representations of various stages of manufacturing the semiconductor structure 100a shown along line B-B′ in FIG. 1E, in accordance with some embodiments.

More specifically, FIG. 2A-1 illustrates the cross-sectional representation shown along line A-A′ ′ in FIG. 1E, in accordance with some embodiments. FIG. 2A-2 illustrates the cross-sectional representation shown along line B-B′ in FIG. 1E in accordance with some embodiments.

As shown in FIGS. 2A-1 and 2A-2, the gate spacer layers 126 are formed on opposite sidewall surfaces of the dummy gate structure 118. The fin spacer layers 128 are formed on opposite sidewall surfaces of the source/drain (S/D) regions of the fin structures 104a/104b.

As shown in FIGS. 2B-1 and 2B-2, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structures 118 and the gate spacer layers 126 are removed in accordance with some embodiments. In addition, some portions of the base fin structure 105 are also recessed to form curved top surfaces, as shown in FIG. 2B-1 in accordance with some embodiments.

In some embodiments, the fin structures 104a/104b are recessed by performing an etching process. The etching process may be an anisotropic etching process, such as dry plasma etching, and the dummy gate structure 118 and the gate spacer layers 126 are used as etching masks during the etching process. In some embodiments, the fin spacer layers 128 are also recessed to form lowered fin spacer layers 128′.

Afterwards, as shown in FIGS. 2C-1 and 2C-2, after the source/drain (S/D) recesses 130 are formed, the first semiconductor material layers 106 exposed by the source/drain (S/D) recesses 130 are laterally recessed to form notches 132, in accordance with some embodiments.

In some embodiments, an etching process is performed on the semiconductor structure 100a to laterally recess the first semiconductor material layers 106 of the fin structure 104a/104b from the source/drain (S/D) recesses 130. In some embodiments, during the etching process, the first semiconductor material layers 106 have a greater etching rate (or etching amount) than the second semiconductor material layers 108, thereby forming notches 132 between adjacent second semiconductor material layers 108. In some embodiments, the etching process is an isotropic etching such as dry chemical etching, remote plasma etching, wet chemical etching, another suitable technique, and/or a combination thereof.

Next, as shown in FIGS. 2D-1 and 2D-2, inner spacer layers 134 are formed in the notches 132 between the second semiconductor material layers 108, in accordance with some embodiments. The inner spacer layers 134 are configured to separate the source/drain (S/D) structures and the gate structures formed in subsequent manufacturing processes in accordance with some embodiments.

In some embodiments, the inner spacer layers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 134 is formed by a deposition process, such as chemical vapor deposition (CVD) process, atomic layer deposition (ALD) process, another applicable process, or a combination thereof.

Afterwards, as shown in FIGS. 2E-1 and 2E-2, after the inner spacer layers 134 are formed, a first source/drain (S/D) structure 136a and a second S/D structure 136b are formed in the S/D recesses 130, in accordance with some embodiments.

In some embodiments, the first source/drain (S/D) structure 136a and the second S/D structure 136b are formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the first source/drain (S/D) structure 136a and the second S/D structure 136b are made of any applicable material, such as Ge, Si, GaAs, AlGaAs, SiGe, GaAsP, SiP, SiC, SiCP, or a combination thereof.

In some embodiments, the first source/drain (S/D) structure 136a and the second S/D structure 136b are in-situ doped during the epitaxial growth process. For example, the first source/drain (S/D) structure 136a and the second S/D structure 136b may be the epitaxially grown SiGe doped with boron (B). For example, the first source/drain (S/D) structure 136a and the second S/D structure 136b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the first source/drain (S/D) structure 136a and the second S/D structure 136b are doped in one or more implantation processes after the epitaxial growth process.

Next, as shown in FIGS. 2F-1 and 2F-2, after the first source/drain (S/D) structure 136a and the second S/D structure 136b are formed, a contact etch stop layer (CESL) 138 is conformally formed to cover the S/D structures 136 and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), or another applicable low-k dielectric material. The ILD layer 140 may be formed by chemical vapor deposition (CVD), physical vapor deposition, (PVD), atomic layer deposition (ALD), or another applicable process.

After the contact etch stop layer 138 and the ILD layer 140 are deposited, a planarization process such as CMP or an etch-back process may be performed until the gate electrode layers 120 of the dummy gate structures 118 are exposed, as shown in FIG. 2F-2 in accordance with some embodiments.

Afterwards, as shown in FIGS. 2G-1 and 2G-2, the dummy gate structure 118 is removed to form a trench 141, in accordance with some embodiments. As a result, the first stack structure 104a and the second stack structure 104b are exposed by the trench 141.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Next, as shown in FIGS. 2H-1 and 2H-2, the first semiconductor material layers 106 are removed to form nanostructures 108′ with the second semiconductor material layers 108, in accordance with some embodiments. The nanostructures 108′ are used as the channel layers of the semiconductor structure 100a.

The first S/D structure 136a and the second S/D structure 136b are attached to the nanostructures 108′ (or channel layers). The first stack structure 104a and the second stack structure 104b includes the nanostructures 108'.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIGS. 2I-1 and 2I-2, after the nanostructures 108′ are formed, a gate structure 142 is formed to surround the nanostructures 108′ and over the isolation structure 110, in accordance with some embodiments. More specifically, the dummy gate structures 118 and the first semiconductor material layers 106 are removed to form nanostructures 108′ with the second semiconductor material layers 108, in accordance with some embodiments.

After the nanostructures 108′ are formed, the gate structure 142 is formed wrapped around the nanostructures 108'. The gate structure 142 wraps around the nanostructures 108′ to form gate-all-around transistor structures in accordance with some embodiments. In some embodiments, the gate structure 142 includes an interfacial layer 144, a gate dielectric layer 146, and a gate electrode layer 148.

In some embodiments, the interfacial layers 144 are oxide layers formed around the nanostructures 108′ and on the top of the base fin structure 105. In some embodiments, the interfacial layers 144 are formed by performing a thermal process.

In some embodiments, the gate dielectric layers 146 are formed over the interfacial layers 144, so that the nanostructures 108′ are surrounded (e.g. wrapped) by the gate dielectric layers 146. In addition, the gate dielectric layers 146 also cover the sidewalls of the gate spacer layers 126 and the inner spacer layers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layer 148 is formed on the gate dielectric layer 146. In some embodiments, the gate electrode layer 148 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 148 is formed using chemical vapor deposition (CVD), atomic layer deposition (ALD), electroplating, another applicable method, or a combination thereof. Other conductive layers, such as work function metal layers, may also be formed in the gate structure 142, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layers 144, the gate dielectric layers 146, and the gate electrode layer 148 are formed, a planarization process such as CMP or an etch-back process may be performed until the ILD layer 140 is exposed.

Afterwards, as shown in FIGS. 2J-1 and 2J-2, an etch stop layer 150 is formed over the gate structure 142, and a dielectric layer 152 is formed over the etch stop layer 150, in accordance with some embodiments.

In some embodiments, the etch stop layer 150 is made of a dielectric materials, such as silicon nitride, silicon oxide, silicon oxynitride, another suitable dielectric material, or a combination thereof. The dielectric material for the etch stop layer 150 may be conformally deposited over the semiconductor structure by performing chemical vapor deposition (CVD), ALD, other application methods, or a combination thereof.

The dielectric layer 152 may include multilayers made of multiple dielectric materials, such as silicon oxide, silicon nitride, silicon oxynitride, phosphosilicate glass (PSG), borophosphosilicate glass (BPSG), or another applicable low-k dielectric material. The dielectric layer 152 may be formed by chemical vapor deposition (CVD), physical vapor deposition, (PVD), atomic layer deposition (ALD), or another applicable process.

Next, as shown in FIGS. 2K-1 and 2K-2, a portion of the CESL 138, a portion of the ILD layer 140, a portion of the etch stop layer 150 and a portion of the dielectric layer 152 are removed to form openings 153, in accordance with some embodiments. As result, the top surface of the first S/D structure 136a and the top surface of the second S/D structure 136b are exposed.

The openings 153 may be formed using a photolithography process and an etching process. In addition, some portions of the first S/D structure 136a and second S/D structure 136b exposed by the contact openings may also be etched during the etching process.

Next, as shown in FIGS. 2L-1 and 2L-2, a layer for example, a barrier layer 154 is conformally formed in the openings 153, in accordance with some embodiments. Next, the bottom portion of the barrier layer 154 is removed by an etching process to expose the top surface of the first S/D structure 136a and the top surface of the second S/D structure 136b.

In some embodiments, the barrier layer 154 is made of dielectric materials, such as silicon nitride, silicon oxide, SiCN, SiOCN, SiCO, AlOx, HfO, or high-k dielectric materials, or another applicable dielectric material. The barrier layer 154 is formed by performing chemical vapor deposition (CVD), atomic layer deposition (ALD), or another applicable process.

Next, as shown in FIGS. 2M-1 and 2M-2, a sacrificial layer 156 is formed on the barrier layer 154, in accordance with some embodiments. The sacrificial layer 156 and the barrier layer 154 are made of different materials. The barrier layer 154 has a high etching selectivity with respect to the sacrificial layer 156. When the sacrificial layer 156 are removed at the following steps, the barrier layer 154 is not removed or removed slightly.

In some embodiments, the sacrificial layer 156 is made of dielectric materials, such as silicon nitride, silicon oxide, AlOx, SiON, or another applicable dielectric material. In some embodiments, the sacrificial layer 156 is formed by chemical vapor deposition (CVD), atomic layer deposition (ALD), or another applicable process.

Next, as shown in FIGS. 2N-1 and 2N-2, a first etching process 15 is performed to remove a portion of the first S/D structure 136a and a portion of the second S/D structure 136b to form a trench 157, in accordance with some embodiments. The barrier layer 154 and the sacrificial layer 156 are used as a mask when performing the first etching process 15. The trench 157 has a sidewall surface without any turning point.

It should be noted that the bottom surface of the trench 157 is lower than the top surface of the first S/D structure 136a and the top surface of the second S/D structure 136b. In addition, the bottom surface of the trench 157 is lower than the topmost nanostructure 108′. In some other embodiments, the bottom surface of the trench 157 is lower than the bottommost nanostructure 108′. In some embodiments, the bottom surface of the trench 157 reaches the third layer of the second semiconductor layer 108. In some embodiments, the bottom surface of the trench 157 reaches the second layer of the second semiconductor layer 108.

In some other embodiments, the first etching process 15 is a dry etching process. In some other embodiments, the etchant used in the first etching process 15 includes fluorine (F)-containing gas, chlorine (Cl)-containing gas or another applicable gas.

Next, as shown in FIGS. 2O-1 and 2O-2, a second etching process 17 is performed to enlarge the trench 157, in accordance with some embodiments. Another portion of the first S/D structure 136a and another portion of the second S/D structure 136b are removed, and the sacrificial layer 156 is removed simultaneously. The width and the depth of the trench 157 are further increased by the second etching process 17. As a result, the trench 157 has a T-shaped structure. The sidewall surface of the trench 157 has a turning point after the second etching process 17.

After the second etching process 17, the bottommost surface of the trench 157 is lower than the top surface of the first S/D structure 136a and the top surface of the second S/D structure 136b. In addition, the bottommost surface of the trench 157 is lower than the bottommost nanostructure 108'. Furthermore, the bottommost surface of the trench 157 is lower than the top surface of the lowered fin spacer layers 128'.

Next, as shown in FIGS. 2P-1 and 2P-2, a metal silicide layer 158 and an S/D contact layer 160 are formed in the opening 153 and the trench 157, in accordance with some embodiments. An S/D contact structure 162 is formed by the metal silicide layer 158 and the S/D contact layer 160. The S/D contact structure 162 is formed on front side of the S/D structure 136a/136b. The barrier layer 154 is not removed, the barrier layer 154 is formed on the sidewall surface of the S/D contact structure 162. The S/D contact structure 162 is surrounded by the barrier layer 154 to protect the S/D contact structure 162.

The metal silicide layers 158 may be formed by forming a metal layer over the top surfaces of the first S/D structure 136a and the second S/D structure 136b and annealing the metal layer so the metal layer reacts with the first S/D structure 136a and the second S/D structure 136b to form the metal silicide layers 158. The unreacted metal layer may be removed after the metal silicide layers 158 are formed. In some embodiments, the metal silicide layers 158 includes WSi, NiSi, TiSi and/or CoSi. In some embodiments, the bottom portion of the metal silicide layers 158 is thicker than the sidewall portion of the metal silicide layers 158.

In some embodiments, the S/D contact layer 160 is made of tungsten (W), ruthenium (Ru), molybdenum (Mo), cobalt (Co), or the like. In some embodiments, the S/D contact layer 160 is formed by performing a deposition process, such as chemical vapor deposition (CVD), physical vapor deposition, (PVD), atomic layer deposition (ALD), or another applicable process.

As shown in FIG. 2P-1, the S/D contact structure 162 has a T-shaped structure with different widths from top to bottom. More specifically, the S/D contact structure 162 has a top portion 162a, a middle portion 162b and a bottom portion 162c. The dot line shown in FIG. 2P-1 is drawn to provide a better understanding of the structure, but there is no actual interface or boundary between the top portion 162a, the middle portion 162b and the bottom portion 162c. The middle portion 162b and the bottom portion 162c are embedded in the S/D structure 136a/136b. The top portion 162a is formed by filling materials into the opening 153, and the middle portion 162b and the bottom portion 162c are formed by filling materials into the trench 157. Since the trench 157 has a T-shaped structure, the middle portion 162b and the bottom portion 162c form the T-shaped structure.

The top portion 162a has the top surface width a first width W₁, the middle portion 162b has a second width W₂, and the bottom portion 162c has the bottom surface with a third width W₃. The first width W₁ of the top portion 162a is different from the second width W₂ of the middle portion 162b, and the second width W₂ of the middle portion 162b is different from the third width W₃ of the bottom portion 162c. In some embodiments, the difference between the second width W₂ and the third width W₃ is about 1 nm to about 10 nm at the S/D region (along the line A-A′ in FIG. 1E).

In some embodiments, the first width W₁ is greater than the second width W₂, and the second width W₂ is greater than the third width W₃. In some embodiments, the S/D contact structure 162 has a sidewall surface, and the sidewall surface has a step shaped structure. In other words, the sidewall surface of the S/D contact structure 162 has two turning points. In addition, the metal silicide layer 154 also has a turning point.

As shown in FIG. 2P-1, at the S/D region (along the line A-A′ in FIG. 1E), the middle portion 162b has a first depth D₁ measured from the top surface of the S/D structure 136a/136b to the interface between the middle portion 162b and the bottom portion 162c (the interface is a turning point). The bottom portion 162c has a second depth D₂ measured from the top surface of the S/D structure 136a/136b to the bottom surface of the bottom portion 162c. The second depth D₂ is greater than the first depth D₁.

As shown in FIG. 2P-2, at the gate region (along the line B-B′ in FIG. 1E), the top portion 162a has the top surface width a fourth width W₄, the middle portion 162b has a fifth width W₅, and the bottom portion 162c has the bottom surface with a sixth width W₆. The fourth width W₄ of the top portion 162a is different from the fifth width W₅ of the middle portion 162b, and the fifth width W₅ of the middle portion 162b is different from the sixth width W₆ of the bottom portion 162c.

In some embodiments, the fourth width W₄ is greater than the fifth width W₅, and the fifth width W₅ is greater than the sixth width W₆. In some embodiments, the difference (W₂−W₃) between the second width W₂ and the third width W₃ is substantially the same as the difference (W₅−W₆) between the fifth width W₅ and the sixth width W₆. In some embodiments, the difference (W₅−W₆)between the fifth width W₅ and the sixth width W₆ is greater than the difference (W₂−W₃) between the second width W₂ and the third width W₃.

In some embodiments, the difference (W₂−W₃) between the second width W₂ and the third width W₃ is about 1 nm to about 10 nm at the S/D region (along the line A-A′ in FIG. 1E). In some embodiments, the difference (W₅−W₆) between the fifth width W₅ and the sixth width W₆ is about 1 nm to about 10 nm at the gate region (along the line B-B′ in FIG. 1E). In some embodiments, the first difference (W₂−W₃) between the second width W₂ and the third width W₃ at the S/D region (along the line A-A′ in FIG. 1E) is comparable to the second difference (W₅−W₆) between the fifth width W₅ and the sixth width W₆. In some embodiments, the difference between first difference and the second difference is about 1 nm. In some other embodiments, the difference between second difference and the first difference is about 1 nm to about 10 nm when the second difference is greater than the first difference.

As shown in FIG. 2P-2, the middle portion 162b has a third depth D₃ measured from the top surface of the S/D structure 136a/136b to the interface between the middle portion 162b and the bottom portion 162c (the interface is a turning point). The bottom portion 162c has a fourth depth D₄ measured from the top surface of the S/D structure 136a/136b to the bottom surface of the bottom portion 162c. The fourth depth D₄ is greater than the third depth D₃.

Furthermore, the metal silicide layer 158 also has step-shaped structure. The bottommost surface of the metal silicide layer 158 is lower than the topmost nanostructure 108′. In some embodiments, the bottommost surface of the metal silicide layer 158 is lower than the bottommost nanostructure 108′.

The bottommost surface of the S/D contact structure 162 is lower than the topmost nanostructure 108′. In some embodiments, the bottommost surface of the S/D contact structure 162 is lower than the bottommost nanostructure 108′. In some embodiments, the bottommost surface of the S/D contact structure 162 is lower than the topmost inner spacer layer 134.

It should be noted that the S/D contact structure 162 is formed by two etching processes, rather than by one etching process, the opening 153 and the trench 157 are formed by different steps, and therefore the aspect ratio is reduced when forming the trench 157. The lower aspect ratio is used to help the filling the contact materials for forming the S/D contact structure 162. In addition, the contact area between the/D contact structure 162 and the S/D structure 136a/136b is increased by forming the T-shaped structure S/D contact structure 162. Therefore, the contact resistance between the S/D contact structure 162 and the S/D structure 136a/136b is reduced.

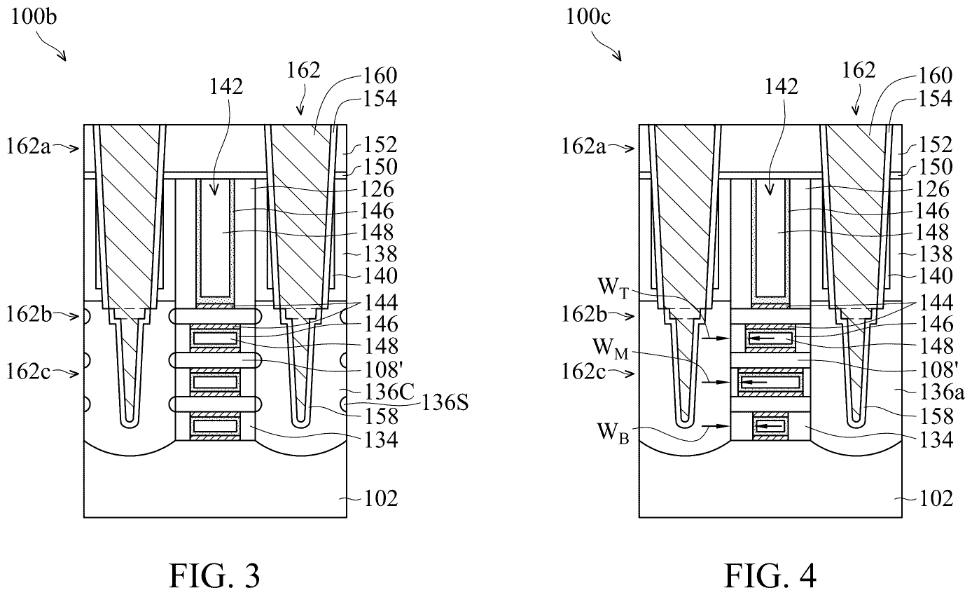

Furthermore, the T-shaped S/D contact structure 162 is in contact with the central portion 136C (shown in FIG. 3) of the S/D structure 136a/136b, and is separated from the sidewall portion 136S (shown in FIG. 3) of the S/D structure 136a/136b. Therefore, the contact resistance between the S/D contact structure 162 and the S/D structure 136a/136b is reduced. The shorting or leakage issue between the S/D contact structure 162 and the gate structure 142 can be reduced. Therefore, the performance of the semiconductor structure 100a is improved.

FIG. 3 illustrates a cross-sectional view of a semiconductor structure 100b, in accordance with some embodiments. The semiconductor structure 100b of FIG. 3 includes elements that are similar to, or the same as, elements of the semiconductor structure 100a of FIGS. 2A-1 to 2P-1 and 2A-2 to 2P-2, the difference between the FIG. 3 and FIGS. 2P-1 and 2P-2 is that the S/D structure 136a/136b includes the sidewall portion 136S and the central portion 136C, the sidewall portion 136S is formed firstly when forming the S/D structure 136a/136b and is in contact with the nanostructures 108′. Since the inner spacer layers 134 are not made of semiconductor materials, and therefore when forming the S/D structure 136a/136b, the sidewall portion 136S is not formed on the inner spacer layers 134. The boundary of the sidewall portion 136S is in direct contact with the interface between the nanostructures 108′ and the inner spacer layers 134.

The first doping concentration of the sidewall portion 136S is smaller than a second doping concentration of the central portion 136C. The S/D contact structure 162 is separated from the sidewall portion 136S of the S/D structure 136a/136b by the central portion 136C. Since the S/D contact structure 162 is not in direct contact with the sidewall portion 136S of the S/D structure 136a/136b, the contact resistance between the S/D contact structure 162 and the S/D structure 136a/136b is reduced.

FIG. 4 illustrates a cross-sectional view of a semiconductor structure 100c, in accordance with some embodiments. The semiconductor structure 100c of FIG. 4 includes elements that are similar to, or the same as, elements of the semiconductor structure 100a of FIGS. 2A-1 to 2P-1 and 2A-2 to 2P-2, the difference between the FIG. 4 and FIGS. 2P-1 and 2P-2 is that the widths of the each of the inner spacer layers 134 are different due to the process control.

In some embodiments, there are three levels of the inner spacer layers 134. The first level of the inner spacer layers 134 has a width W_{B}. The second level of the inner spacer layers 134 has a width W_{M}. The third level of the inner spacer layers 134 has a width W_{T}. In some embodiments, the width W_{B} is greater than the width W_{T}, and the width W_{T} is greater than the width W_{M}.

In other words, the gate structure 142 has different withs when the inner spacer layers 134 with different widths. The gate structure 142 has different widths along the first direction (the extending direction of the nanostructures 108′). In some embodiments, a sidewall surface of a portion of the ate structure 142 extends beyond an inner sidewall surface of the gate spacer layer 126.

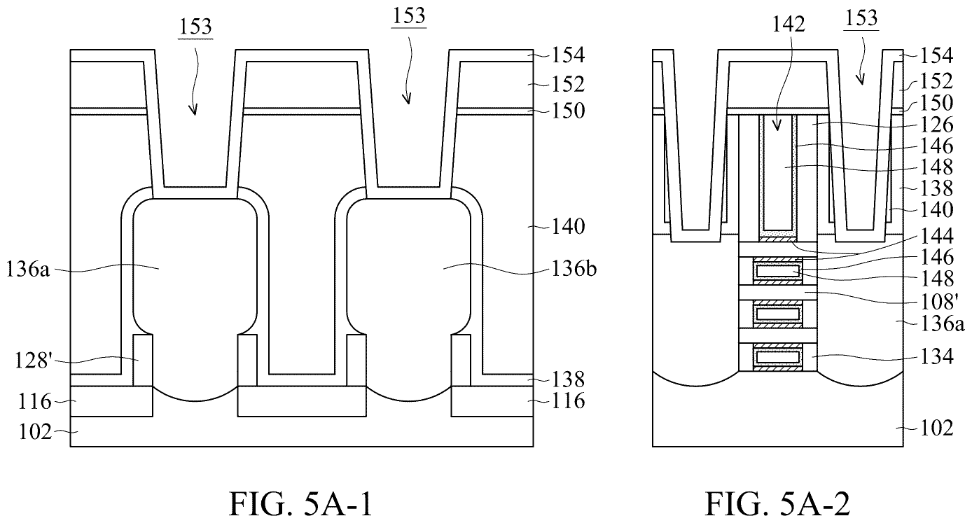

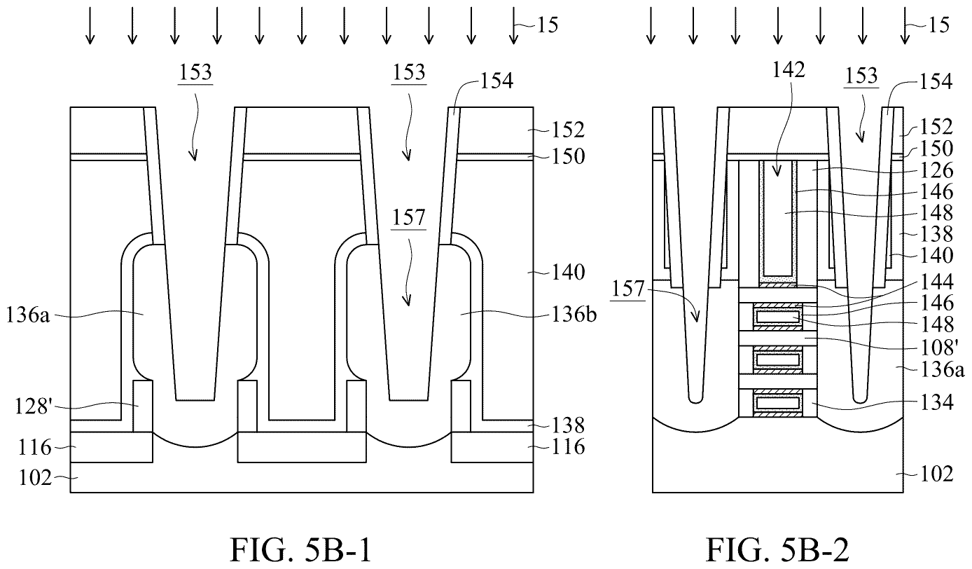

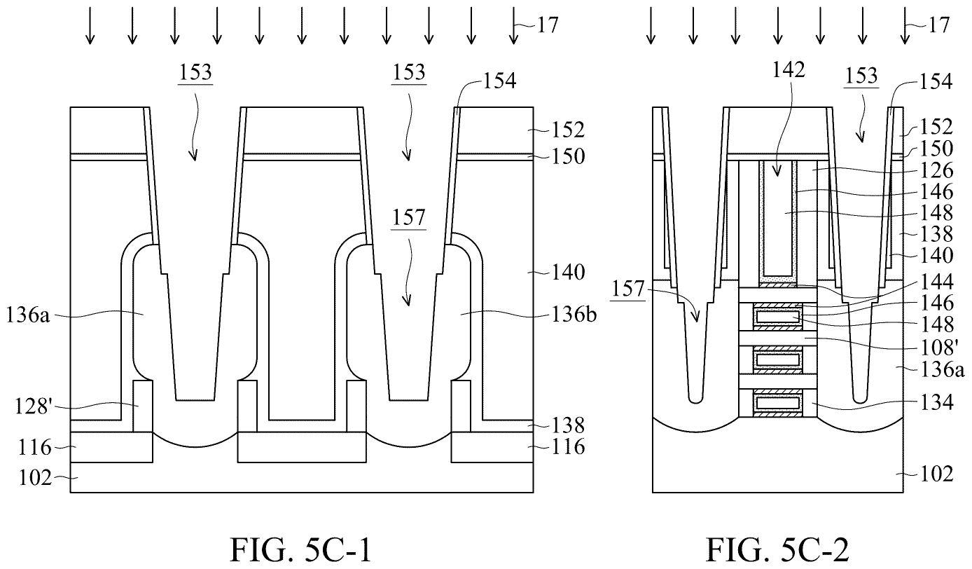

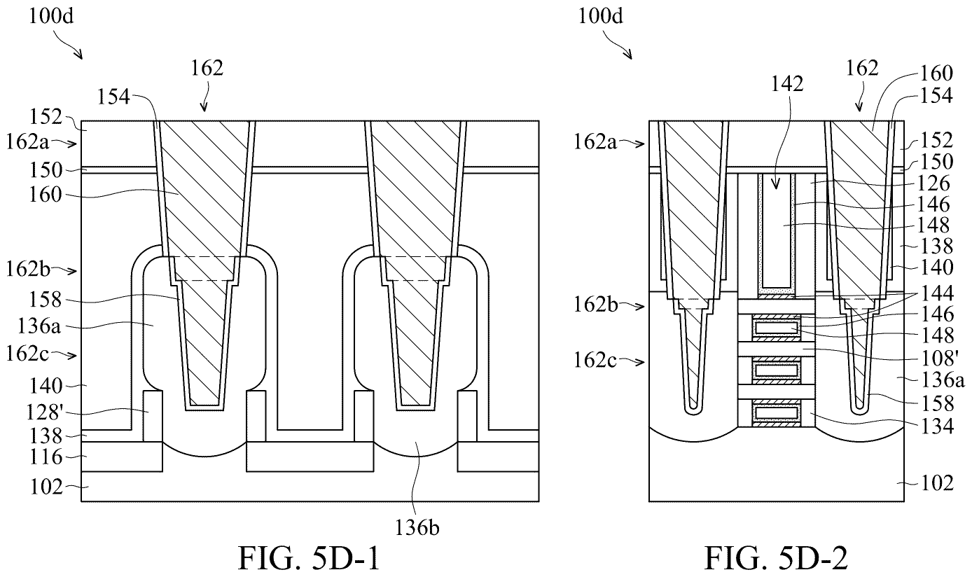

FIGS. 5A-1 to 5D-1 illustrate cross-sectional representations of various stages of manufacturing a semiconductor structure 100d shown along line A-A′ in FIG. 1E, in accordance with some embodiments. FIGS. 5A-2 to 5D-2 illustrate cross-sectional representations of various stages of manufacturing the semiconductor structure 100d shown along line B-B′ in FIG. 1E, in accordance with some embodiments. The semiconductor structure 100e of FIGS. 5A-1 to 5D-1 and 5A-2 to 5D-2 includes elements that are similar to, or the same as, elements of the semiconductor structure 100a of FIGS. 2A-1 to 2P-1 and 2A-2 to 2P-2.

As shown in FIGS. 5A-1 and 5A-2, the barrier layer 154 is formed on the sidewall surface and the bottom surface of the opening 153. The thickness of the barrier layer 154 shown in FIGS. 5A-1 and 5A-2 is thicker than the thickness of the barrier layer 154 shown in FIGS. 2L-1 and 2L-2.

Next, as shown in FIGS. 5B-1 and 5B-2, the first etching process 15 is performed to remove a portion of the first S/D structure 136a and a portion of the second S/D structure 136b to form a trench 157, in accordance with some embodiments. The trench 157 has a sidewall surface without any turning point. The barrier layer 154 is used as a mask when performing the first etching process 15.

It should be noted that the bottom surface of the trench 157 is lower than the top surface of the first S/D structure 136a and the top surface of the second S/D structure 136b. In addition, the bottom surface of the trench 157 is lower than the topmost nanostructure 108′. In some other embodiments, the bottom surface of the trench 157 is lower than the bottommost nanostructure 108′.

After wards, as shown in FIGS. 5C-1 and 5C-2, the second etching process 17 is performed to enlarge the trench 157, in accordance with some embodiments. Another portion of the first S/D structure 136a and another portion of the second S/D structure 136b are removed, and the sacrificial layer 156 is removed simultaneously. The width and the depth of the trench 157 are further increased by the second etching process 17. As a result, the trench 157 has a T-shaped structure. The sidewall surface of the trench 157 has a turning point after the second etching process 17.

After the second etching process 17, the bottommost surface of the trench 157 is lower than the top surface of the first S/D structure 136a and the top surface of the second S/D structure 136b. In addition, the bottommost surface of the trench 157 is lower than the bottommost nanostructure 108′. Furthermore, the bottommost surface of the trench 157 is lower than the top surface of the lowered fin spacer layers 128′.

Next, as shown in FIGS. 5D-1 and 5D-2, the metal silicide layer 158 and the S/D contact layer 160 are formed in the opening 153 and the trench 157, in accordance with some embodiments. The S/D contact structure 162 is formed by the metal silicide layer 158 and the S/D contact layer 160. The barrier layer 154 is still formed on the sidewall surface of the S/D contact structure 162.

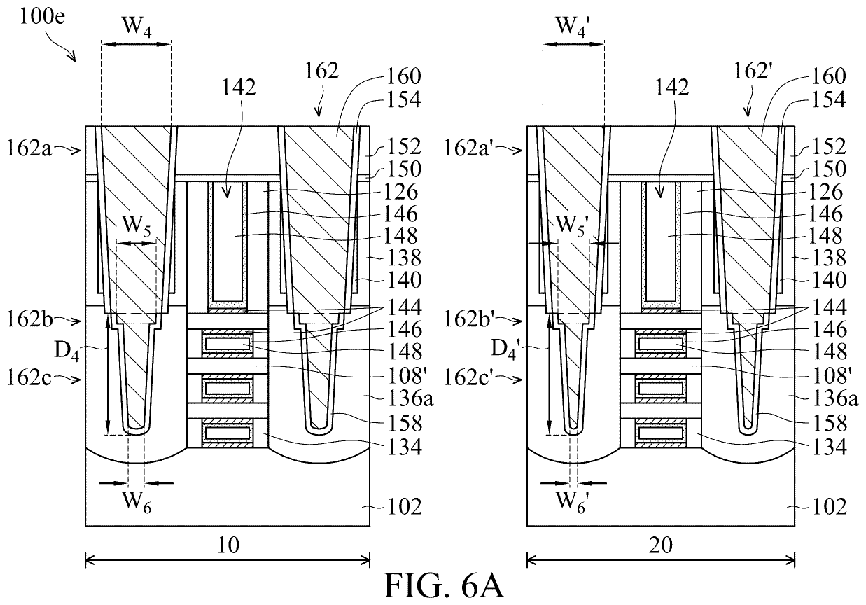

FIG. 6A illustrates a cross-sectional view of a semiconductor structure 100e, in accordance with some embodiments. The semiconductor structure 100e of FIG. 6A includes elements that are similar to, or the same as, elements of the semiconductor structure 100a of FIGS. 2A-1 to 2P-1 and 2A-2 to 2P-2.

As shown in FIG. 6A, there are first region 10 and the second region 20. The S/D contact structure 162 is formed in the first region 10, and the S/D contact structure 162′ is formed in the second region 20. In some embodiments, the semiconductor structure 100e in the first region 10 is a NMOS device, and the semiconductor structure 100e in the second region 20 is a PMOS device.

In some embodiments, the fourth width W₄′ of the top portion 162′a of the S/D contact structure 162′ in the second region 20 is smaller than the fourth width W₄ of the top portion 162a of the S/D contact structure 162 in the first region 10. In some embodiments, the fifth width W₅′ of the middle portion 162′b of the S/D contact structure 162′ in the second region 20 is smaller than the fifth width W₅ of the top portion 162a of the S/D contact structure 162 in the first region 10. In some embodiments, the sixth width W₆′ of the bottom portion 162′c of the S/D contact structure 162′ in the second region 20 is smaller than the sixth width W₆ of the bottom portion 162a of the S/D contact structure 162 in the first region 10.

In some embodiments, the fourth depth D₄′ of the bottom portion 162′c of the S/D contact structure 162′ in the second region 20 is smaller than the fourth depth D₄ of the bottom portion 162c of the S/D contact structure 162 in the first region 10.

FIG. 6B illustrates a cross-sectional view of the semiconductor structure 100e, in accordance with some embodiments. The semiconductor structure 100e of FIG. 6B includes elements that are similar to, or the same as, elements of the semiconductor structure 100a of FIGS. 2A-1 to 2P-1 and 2A-2 to 2P-2.

As shown in FIG. 6B, there are first region 10 and the second region 20. The S/D contact structure 162 is formed in the first region 10, and the S/D contact structure 162′ is formed in the second region 20. In some embodiments, the semiconductor structure 100e in the first region 10 is a NMOS device, and the semiconductor structure 100e in the second region 20 is a PMOS device.

In some embodiments, the first width W₁′ of the top portion 162′a of the S/D contact structure 162′ in the second region 20 is smaller than the first width W₁ of the top portion 162a of the S/D contact structure 162 in the first region 10. In some embodiments, the second width W₂′ of the middle portion 162′b of the S/D contact structure 162′ in the second region 20 is smaller than the second width W₂ of the top portion 162a of the S/D contact structure 162 in the first region 10. In some embodiments, the third width W₃′ of the bottom portion 162′c of the S/D contact structure 162′ in the second region 20 is smaller than the third width W₃ of the bottom portion 162a of the S/D contact structure 162 in the first region 10.

In some embodiments, the second depth D₂′ of the bottom portion 162′c of the S/D contact structure 162′ in the second region 20 is smaller than the second depth D₂ of the bottom portion 162c of the S/D contact structure 162 in the first region 10.

FIGS. 7A-1 to 7C-1 illustrate cross-sectional representations of various stages of manufacturing a semiconductor structure 100f shown along line A-A′ in FIG. 1E, in accordance with some embodiments. FIGS. 7A-2 to 7C-2 illustrate cross-sectional representations of various stages of manufacturing the semiconductor structure 100f shown along line B-B′ in FIG. 1E, in accordance with some embodiments. The semiconductor structure 100f of FIGS. 7A-1 to 7C-1 and 7A-2 to 7C-2 includes elements that are similar to, or the same as, elements of the semiconductor structure 100a of FIGS. 2A-1 to 2P-1 and 2A-2 to 2P-2.

As shown in FIGS. 7A-1 and 7A-2, the barrier layer 154 is formed on the sidewall surface and the bottom surface of the opening 153. The first etching process 15 is performed to remove a portion of the first S/D structure 136a and a portion of the second S/D structure 136b to form a trench 157, in accordance with some embodiments. The barrier layer 154 and the sacrificial layer 156 are used as a mask when performing the first etching process 15. The trench 157 is below the opening 153.

Next, as shown in FIGS. 7B-1 and 7B-2, the second etching process 17 is performed to enlarge the trench 157, in accordance with some embodiments. Another portion of the first S/D structure 136a and another portion of the second S/D structure 136b are removed, and the sacrificial layer 156 is removed simultaneously. The width and the depth of the trench 157 are further increased by the second etching process 17. As a result, the width of trench 157 is greater than the smallest width of the opening 153. The top portion of the first S/D structure 136a and top portion of the second S/D structure 136b in FIGS. 7B-1 and 7B-2 are removed to a greater extent than that in FIGS. 2O-1 and 2O-2.

After the second etching process 17, the bottommost surface of the trench 157 is lower than the top surface of the first S/D structure 136a and the top surface of the second S/D structure 136b. In addition, the bottommost surface of the trench 157 is lower than the bottommost nanostructure 108′. Furthermore, the bottommost surface of the trench 157 is lower than the top surface of the lowered fin spacer layers 128′.

Afterwards, as shown in FIGS. 7C-1 and 7C-2, the metal silicide layer 158 and an S/D contact layer 160 are formed in the opening 153 and the trench 157 to form the S/D contact structure 162, in accordance with some embodiments

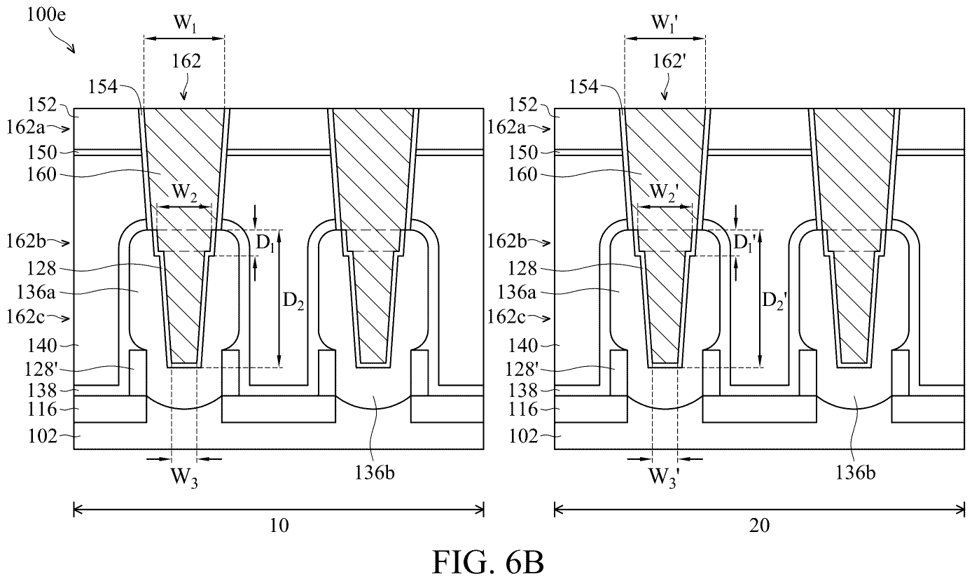

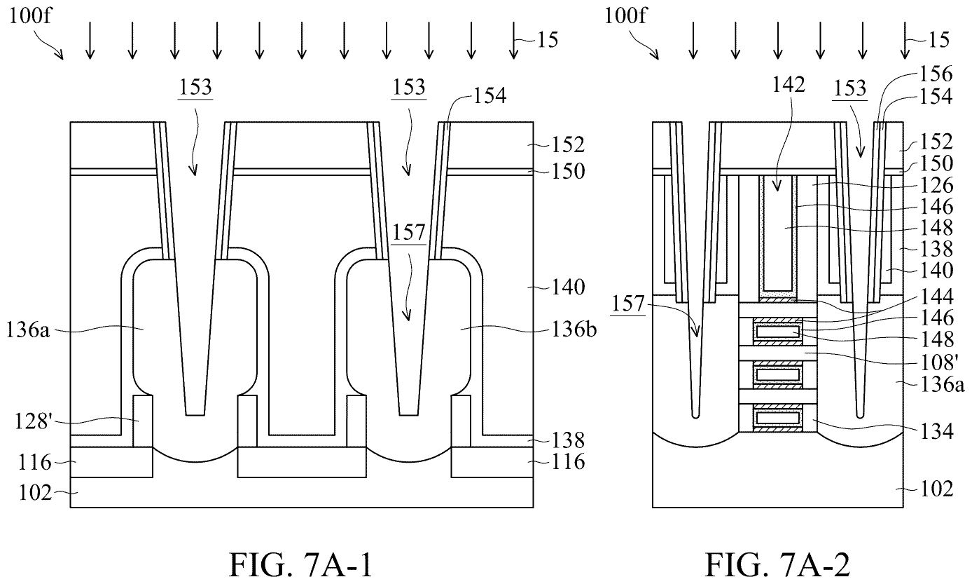

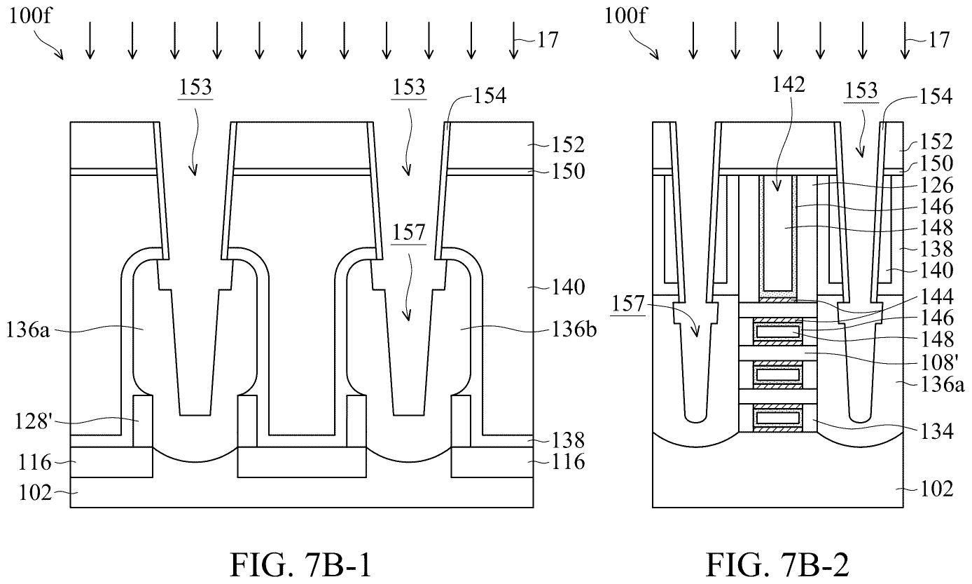

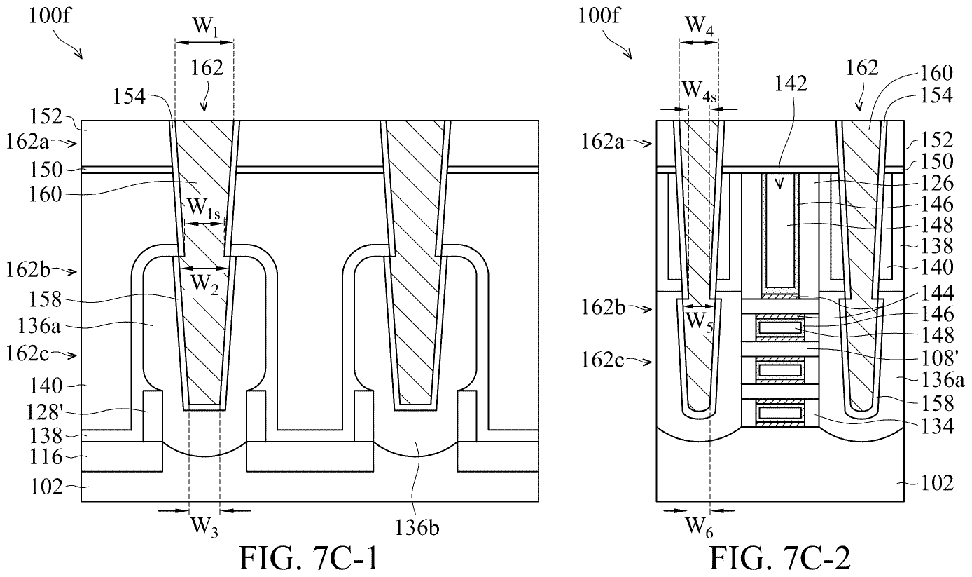

As shown in FIG. 7C-1, the S/D contact structure 162 has the top portion 162a, the middle portion 162b and the bottom portion 162c. The middle portion 162b and the bottom portion 162c are embedded in the S/D structure 136a/136b. The middle portion 162b and the bottom portion 162c forms a V-shaped structure. It should be noted that the greatest width W₂ of the middle portion 162b of the S/D contact structure 162 is greater than the smallest width W₁ₛ of the top portion 162a of the S/D contact structure 162. In addition, the outermost sidewall surface of the metal silicide layer 158 extends beyond the sidewall surface of the barrier layer 154.

As shown in FIG. 7C-2, the greatest width W₅ of the middle portion 162b of the S/D contact structure 162 is greater than the smallest width W₄ₛ of the top portion 162a of the S/D contact structure 162.

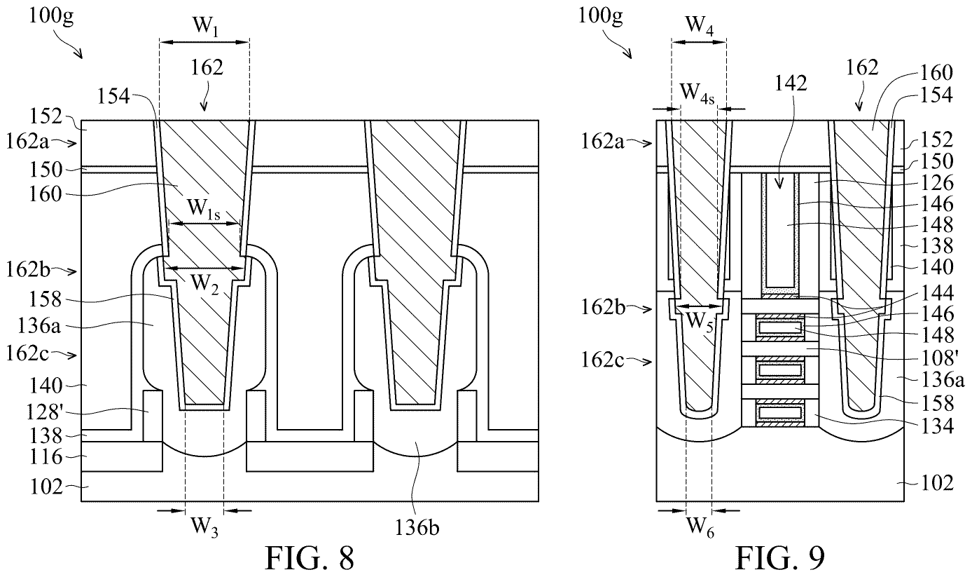

FIG. 8 illustrates a cross-sectional view of a semiconductor structure 100g, in accordance with some embodiments. The semiconductor structure 100g of FIG. 8 includes elements that are similar to, or the same as, elements of the semiconductor structure 100f of FIG. 7C-1, the difference between the FIG. 8 and FIG. 7C-1 is that the middle portion 162b and the bottom portion 162c of the S/D contact structure 162 forms a T-shaped structure.

Not that the semiconductor structure 100a of FIG. 2P-1 is similar to the semiconductor structure 100g of FIG. 8, both of the S/D contact structure 162 of semiconductor structure 100a and the S/D contact structure 162 of the semiconductor structure 100g have T-shaped structure. In the semiconductor structure 100f of FIG. 8, the greatest width W₂ of the middle portion 162b of the S/D contact structure 162 is larger than the smallest width W₁ₛ of the top portion 162a of the S/D contact structure 162.

FIG. 9 illustrates a cross-sectional view of the semiconductor structure 100g, in accordance with some embodiments. The semiconductor structure 100g of FIG. 9 includes elements that are similar to, or the same as, elements of the semiconductor structure 100f of FIG. 7C-2, the difference between the FIG. 9 and FIG. 7C-2 is that the middle portion 162b and the bottom portion 162c of the S/D contact structure 162 forms a T-shaped structure in FIG. 9.

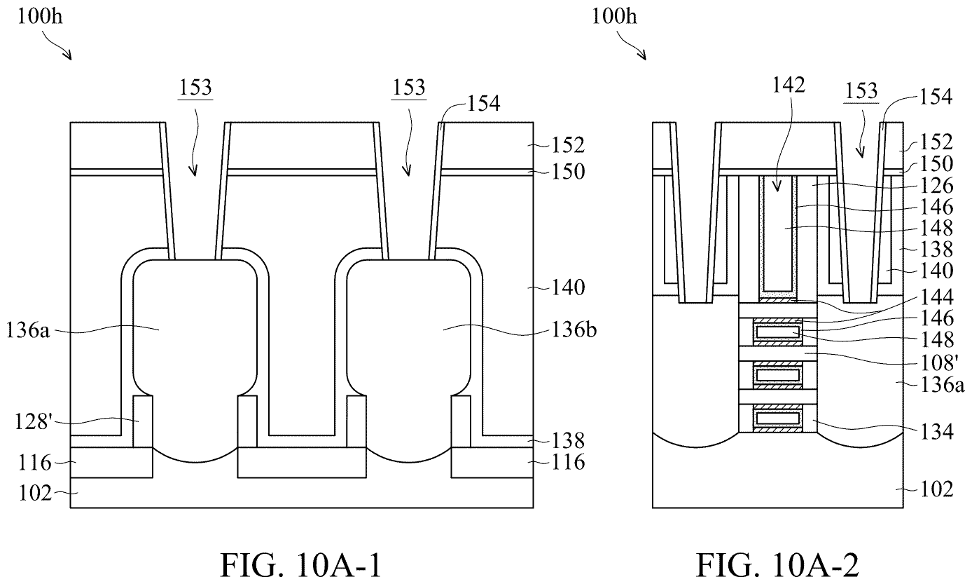

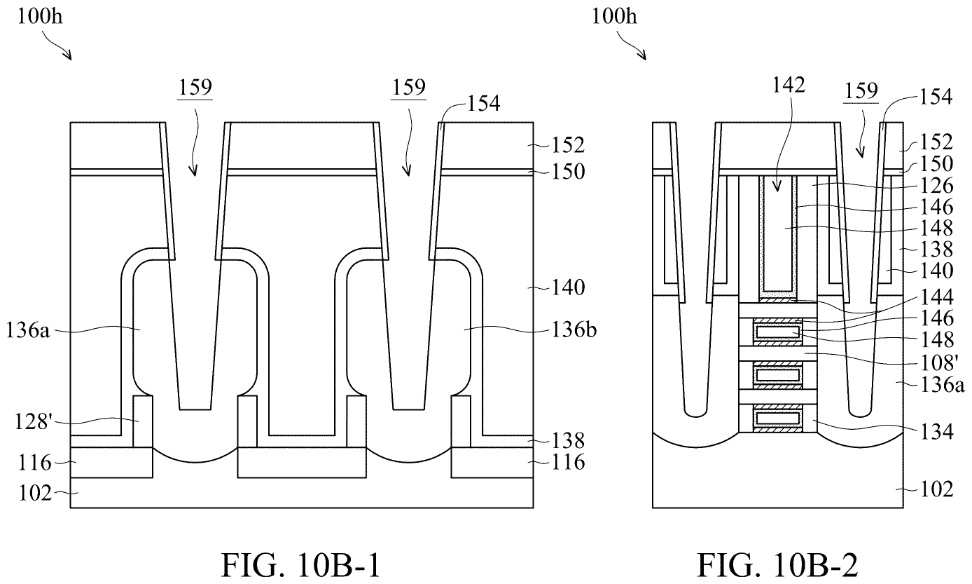

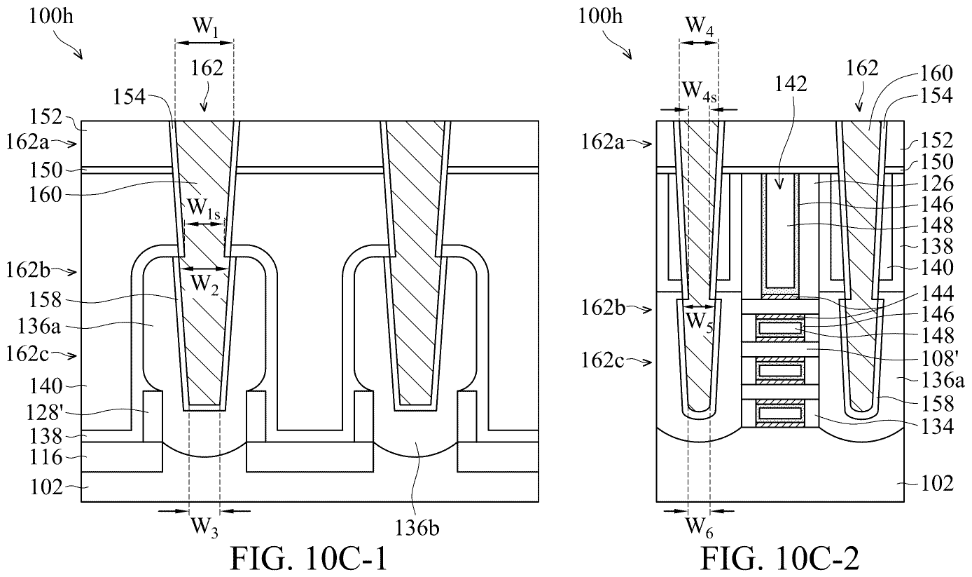

FIGS. 10A-1 to 10C-1 illustrate cross-sectional representations of various stages of manufacturing a semiconductor structure 100h shown along line A-A′ in FIG. 1E, in accordance with some embodiments. FIGS. 10A-2 to 10C-2 illustrate cross-sectional representations of various stages of manufacturing the semiconductor structure 100h shown along line B-B′ in FIG. 1E, in accordance with some embodiments. The semiconductor structure 100h of FIGS. 10A-1 to 10C-1 and 10A-2 to 10C-2 includes elements that are similar to, or the same as, elements of the semiconductor structure 100a of FIGS. 2A-1 to 2P-1 and 2A-2 to 2P-2.

FIGS. 10A-1 and 10A-2 are similar to, or the same as, FIGS. 2L-1 and 2L-2. The barrier layer 154 is conformally formed in the openings 153, in accordance with some embodiments. Next, the bottom portion of the barrier layer is removed by an etching process to expose the top surface of the first S/D structure 136a and the top surface of the second S/D structure 136b.

Next, as shown in FIGS. 10B-1 and 10B-2, a portion of the first S/D structure 136a and a portion of the second S/D structure 136b are removed to form a trench 159, in accordance with some embodiments. As a result, the middle portion of the trench 159 is greater than the smallest width of the top portion of the trench 159. The middle portion and the bottom portion of the trench 159 has a V-shaped structure.

Afterwards, as shown in FIGS. 10C-1 and 10C-2, the metal silicide layer 158 and the S/D contact layer 160 are formed in the trench 159, in accordance with some embodiments. The S/D contact structure 162 is formed by the metal silicide layer 158 and the S/D contact layer 160. The barrier layer 154 is not removed, the barrier layer 154 is formed on the sidewall surface of the S/D contact structure 162. The S/D contact structure 162 is surrounded by the barrier layer 154 to protect the S/D contact structure 162. the S/D contact structure 162 has the top portion 162a, the middle portion 162b and the bottom portion 162c. The middle portion 162b and the bottom portion 162c are embedded in the S/D structure 136a/136b. The middle portion 162b and the bottom portion 162c forms a V-shaped structure. It should be noted that the greatest width W₂ of the middle portion 162b of the S/D contact structure 162 is wider than the smallest width W₁ₛ of the top portion 162a of the S/D contact structure 162.

FIGS. 11A-1 to 11C-1 illustrate cross-sectional representations of various stages of manufacturing a semiconductor structure 100i shown along line A-A′ in FIG. 1E, in accordance with some embodiments. FIGS. 11A-2 to 11C-2 illustrate cross-sectional representations of various stages of manufacturing the semiconductor structure 100i shown along line B-B′ in FIG. 1E, in accordance with some embodiments. The semiconductor structure 100h of FIGS. 11A-1 to 11C-1 and 11A-2 to 11C-2 includes elements that are similar to, or the same as, elements of the semiconductor structure 100a of FIGS. 2A-1 to 2P-1 and 2A-2 to 2P-2.

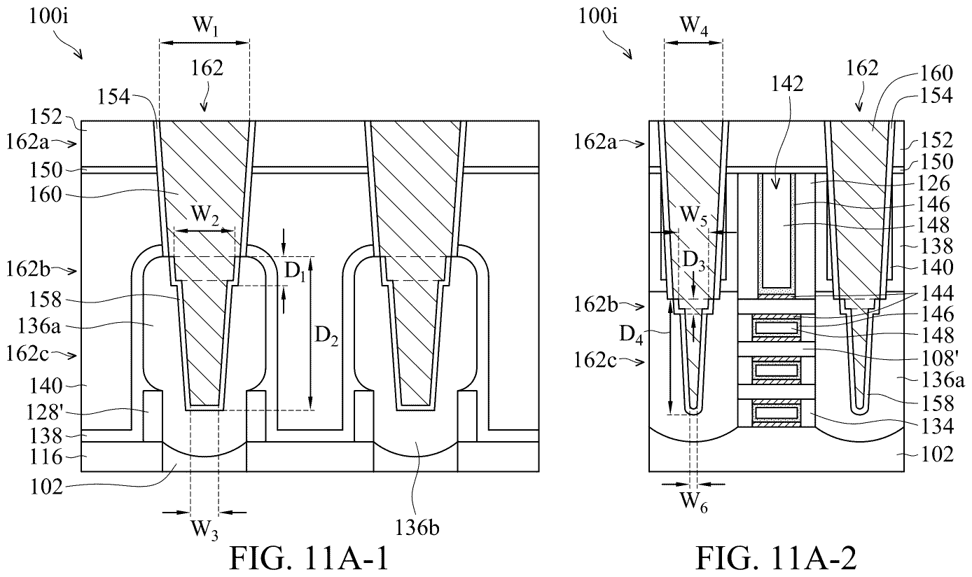

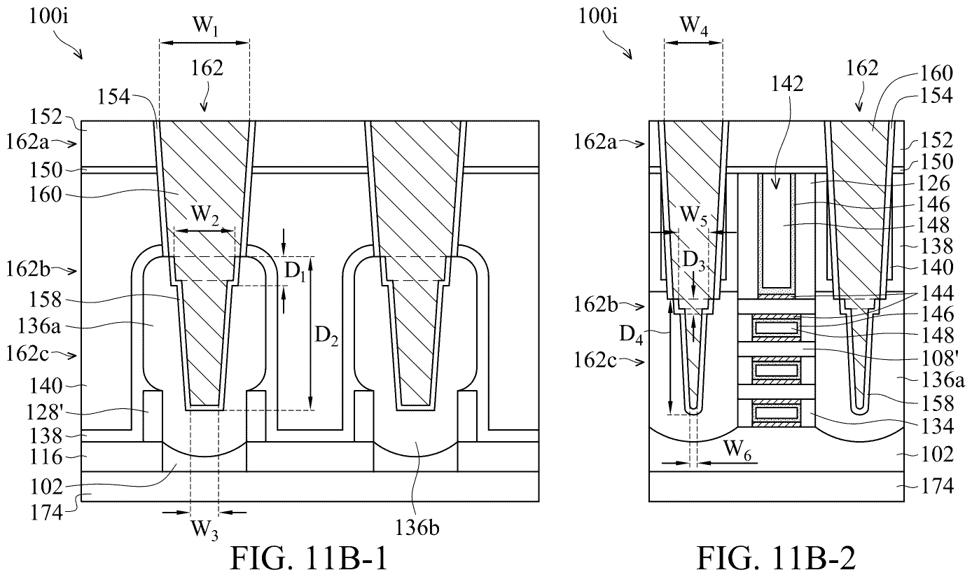

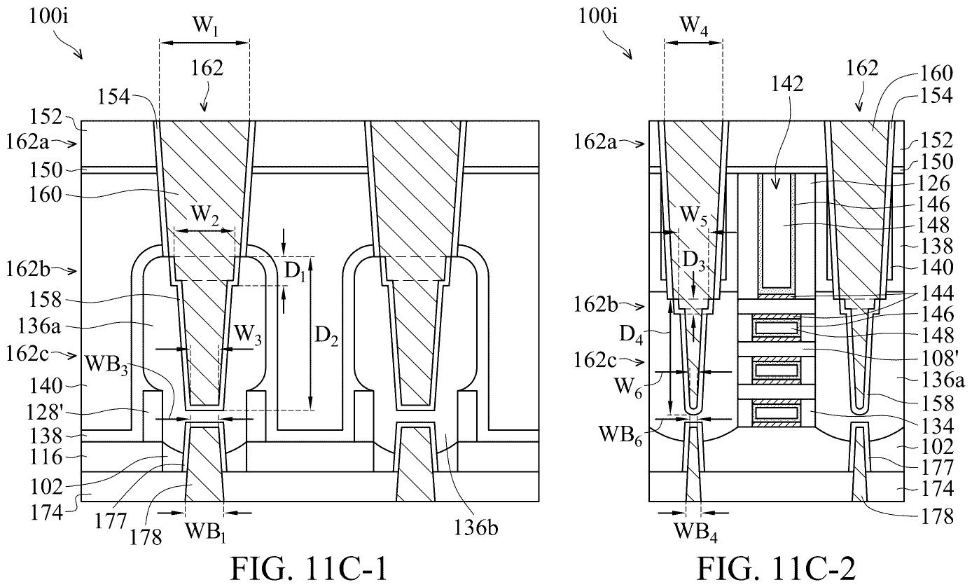

FIG. 11A-1 is after the step of FIG. 2P-1, and FIG. 11A-2 is after the step of FIG. 2P-2. As shown in FIGS. 11A-1 and 11A-2, a portion of the substrate 102 is removed.

Afterwards, as shown in FIGS. 11B-1 and 11B-2, after the portion of the substrate 102 is removed, and a dielectric layer 174 is formed below the isolation structure 116, in accordance with some embodiments. More specifically, a support wafer (not shown) is formed on the dielectric layer 152, and the semiconductor structure 100a is flipped over. Next, then the portion of the substrate 102 is removed to expose the isolation structure 116, and then the dielectric layer 174 is formed on the isolation structure 116. Next, the support wafer (not shown) is removed.

The dielectric layer 174 may include multilayers made of multiple dielectric materials, such as silicon oxide, silicon nitride, silicon oxynitride, phosphosilicate glass (PSG), borophosphosilicate glass (BPSG), or another applicable low-k dielectric material. The dielectric layer 174 may be formed by chemical vapor deposition (CVD), physical vapor deposition, (PVD), atomic layer deposition (ALD), or another applicable process.

Next, as shown in FIGS. 11C-1 and 11C-2, a metal silicide layer 177 and a back-side contact structure 178 are formed through the first S/D structure 136a and the second S/D structure 136b, the substrate 102, the isolation structure 116 and the dielectric layer 174, in accordance with some embodiments. The back-side contact structure 178 is used to connect to a power rail. The metal routing area at the front side can be reduced.

More specifically, the metal silicide layer 177 is between the first S/D structure 136a and the back-side contact structure 178, and between the second S/D structure 136b and the back-side contact structure 178. The back-side contact structure 178 is formed through the bottom portion of the first S/D structure 136a and the bottom portion of the second S/D structure 136b. The topmost surface of the back-side contact structure 178 is higher than the bottommost surface of the gate structure 142. The topmost surface of the back-side contact structure 178 is higher than the bottommost surface of the gate dielectric layer 146. In addition, the topmost surface of the back-side contact structure 178 is higher than the bottommost surface of the inner spacer layer 134.

A trench is formed through the dielectric layer 174, the substrate 102, the first S/D structure 136a, the second S/D structure 136b, and a conductive material is formed in the trench to form the back-side contact structure 178.

The bottommost surface of the S/D contact structure 162 is separated from the topmost surface of the back-side contact structure 178. The bottommost surface of the S/D contact structure 162 is not in contact with the topmost surface of the back-side contact structure 178.

The back-side contact structure 178 has a bottommost surface with a width of W_{B1} and a topmost surface with a width of W_{B3}. The topmost surface of the back-side contact structure 178 is closer to the S/D contact structure 162 than the bottommost surface of the back-side contact structure 178.

The back-side contact structure 178 may include a barrier layer and a conductive layer. In some other embodiments, the back-side contact structure 178 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or another applicable process.

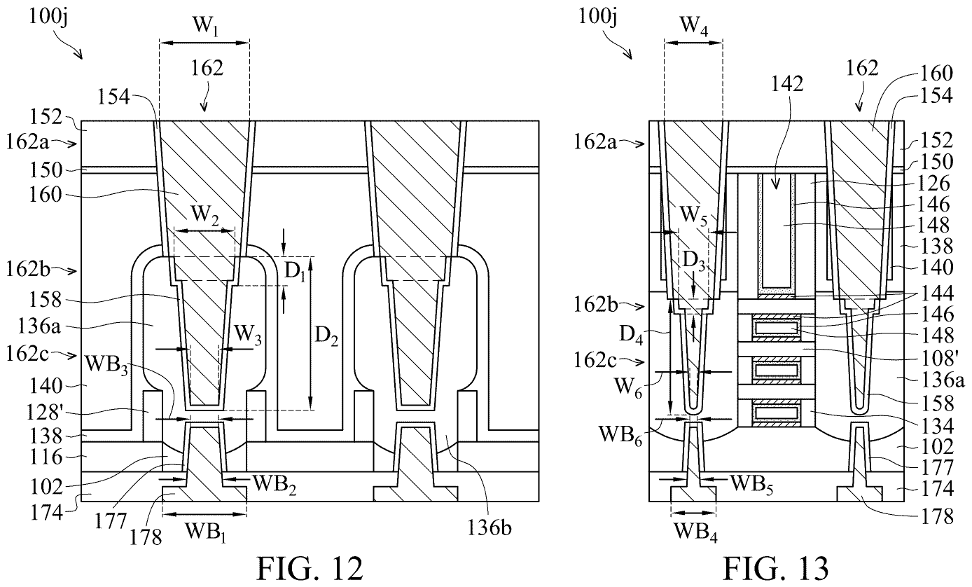

FIG. 12 illustrates a cross-sectional view of a semiconductor structure 100j, in accordance with some embodiments. The semiconductor structure 100j of FIG. 12 includes elements that are similar to, or the same as, elements of the semiconductor structure 100i of FIG. 11C-1, the difference between the FIG. 12 and FIG. 11C-1 is that the back-side contact structure 178 has a reversed-T-shaped structure. In other words, the back-side contact structure 178 has a step-shaped structure. More specifically, the back-side contact structure 178 has a bottommost surface with a width W_{B1}, a middle portion with a width W_{B2}, and a topmost surface with a width of W_{B3}. The topmost surface of the back-side contact structure 178 is closer to the S/D contact structure 162 than the bottommost surface of the back-side contact structure 178. The width W_{B1} is greater than the width W_{B2}. The width W_{B3} is greater than the width W_{B2}. In some embodiments, the difference between the width W_{B1} and the third width W_{B2} is about 1 nm to about 10 nm.

The width W_{B3} of the topmost surface of the back-side contact structure 178 is smaller than the width W_{B1} of the bottommost surface of the back-side contact structure 178. In addition, the third width W₃ of the bottom portion 162c of the S/D contact structure 162 is smaller than the width W_{B3} of the back-side contact structure 178. In addition, the difference between width W_{B3} of the back-side contact structure 178 and the third width W₃ of the bottom portion 162c of the S/D contact structure 162 is in a range about 1 nm to about 10 nm. In some embodiments, the front side S/D contact structure 162 is in direct contact with the back side contact structure 178. In some embodiments, the front side S/D contact structure 162 is and electrically connected to the back side contact structure 178.

FIG. 13 illustrates a cross-sectional view of a semiconductor structure 100j, in accordance with some embodiments. The semiconductor structure 100j of FIG. 13 includes elements that are similar to, or the same as, elements of the semiconductor structure 100i of FIG. 11C-1, the difference between the FIG. 13 and FIG. 11C-2 is that the back-side contact structure 178 has a reversed-T-shaped structure. More specifically, the back-side contact structure 178 has the bottom surface with a width W_{B4} and a middle portion with a width W_{B5} and the top surface with a width W_{B6}. The width W_{B4} is greater than the width W_{B5}.

In some embodiments, the difference between the width W_{B1} and the width W_{B2} is about 1 nm to about 10 nm at the S/D region (along the line A-A′ in FIG. 1E). In some embodiments, the difference between the width W_{B4} and the width W_{B5} is about 1 nm to about 10 nm at the gate region (along the line B-B′ in FIG. 1E). In some embodiments, the first difference between W_{B1} and W_{B2} at the S/D region (along the line A-A′ in FIG. 1E) is comparable to the second difference between W_{B4} and W_{B5}. In some embodiments, the difference between first difference and the second difference is about 1 nm. In some other embodiments, the difference between second difference and the first difference is about 1 nm to about 10 nm when the second difference is greater than the first difference. In some embodiments, the front side S/D contact structure 162 is in direct contact with the back side contact structure 178. In some embodiments, the front side S/D contact structure 162 is electrically connected to the back side contact structure 178.

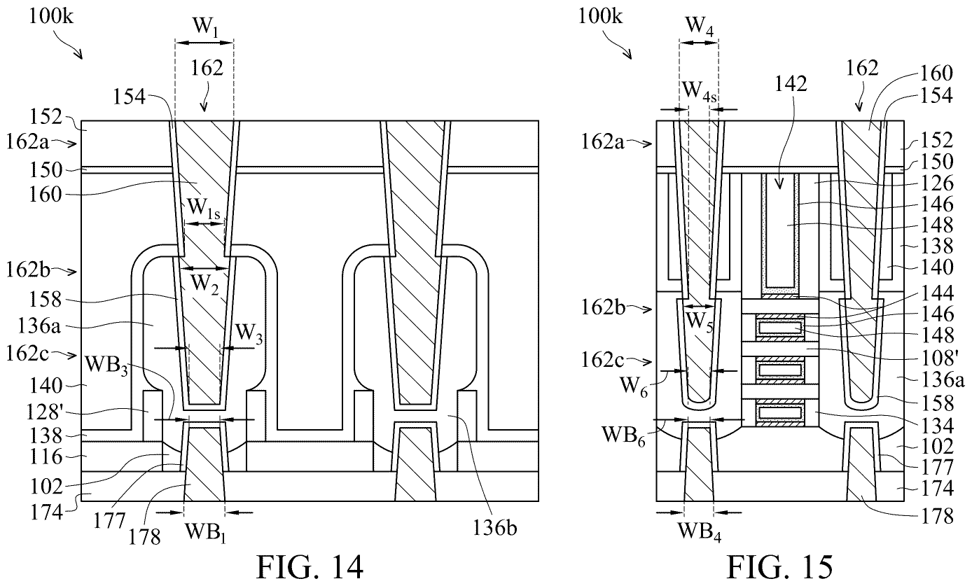

FIG. 14 illustrates a cross-sectional view of a semiconductor structure 100k, in accordance with some embodiments. The semiconductor structure 100k of FIG. 14 includes elements that are similar to, or the same as, elements of the semiconductor structure 100f of FIG. 7C-1, the difference between the FIG. 14 and FIG. 7C-1 is that the metal silicide layer 177 and the back-side contact structure 178 is formed on the back-side of the first S/D structure 136a and the second S/D structure 136b. More specifically, the metal silicide layer 177 and the back-side contact structure 178 is formed through the first S/D structure 136a and the second S/D structure 136b, the substrate 102 and the dielectric layer 174, in accordance with some embodiments. In some embodiments, the front side S/D contact structure 162 is in direct contact with the back side contact structure 178. In some embodiments, the front side S/D contact structure 162 is electrically connected to the back side contact structure 178.

FIG. 15 illustrates a cross-sectional view of the semiconductor structure 100k, in accordance with some embodiments. The semiconductor structure 100k of FIG. 15 includes elements that are similar to, or the same as, elements of the semiconductor structure 100f of FIG. 7C-2, the difference between the FIG. 15 and FIG. 7C-2 is that the metal silicide layer 177 and the back-side contact structure 178 is formed on the back-side of the first S/D structure 136a and the second S/D structure 136b. In some embodiments, the front side S/D contact structure 162 is in direct contact with the back side contact structure 178. In some embodiments, the front side S/D contact structure 162 is electrically connected to the back side contact structure 178.

FIG. 16 illustrates a cross-sectional view of a semiconductor structure 100l, in accordance with some embodiments. The semiconductor structure 100l of FIG. 16 includes elements that are similar to, or the same as, elements of the semiconductor structure 100f of FIG. 7C-1, the difference between the FIG. 16 and FIG. 7C-1 is that the back-side contact structure 178 has a reversed-T-shaped structure. More specifically, the back-side contact structure 178 has a bottom surface with a width W_{B1} and a middle portion with a width W_{B2}. The width W_{B1} is greater than the width W_{B2}. In some embodiments, the front side S/D contact structure 162 is in direct contact with the back side contact structure 178. In some embodiments, the front side S/D contact structure 162 is electrically connected to the back side contact structure 178.

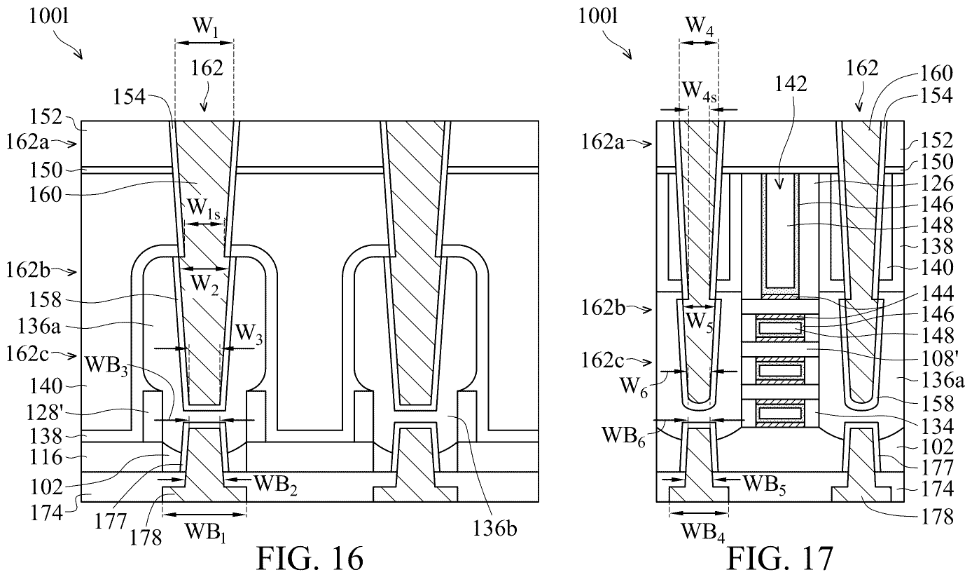

FIG. 17 illustrates a cross-sectional view of the semiconductor structure 100l, in accordance with some embodiments. The semiconductor structure 100l of FIG. 17 includes elements that are similar to, or the same as, elements of the semiconductor structure 100f of FIG. 7C-2, the difference between the FIG. 17 and FIG. 7C-2 is that the back-side contact structure 178 has a reversed-T-shaped structure. More specifically, the back-side contact structure 178 has a bottom surface with a width W_{B4} and a middle portion with a width W_{B5}. The width W_{B4} is greater than the width W_{B5}. In some embodiments, the front side S/D contact structure 162 is in direct contact with the back side contact structure 178. In some embodiments, the front side S/D contact structure 162 is electrically connected to the back side contact structure 178.

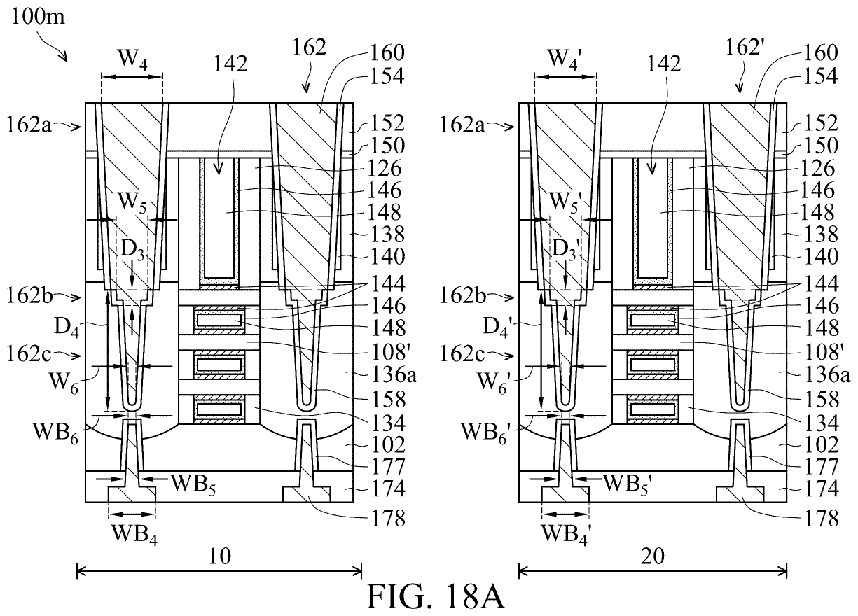

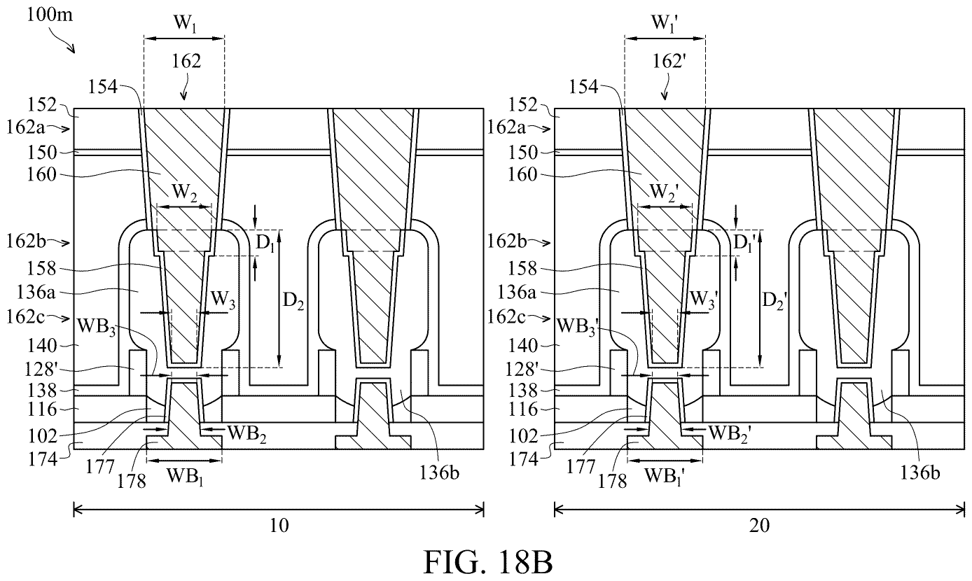

FIG. 18A illustrates a cross-sectional view of a semiconductor structure 100m, in accordance with some embodiments. The semiconductor structure 100m of FIG. 18A includes elements that are similar to, or the same as, elements of the semiconductor structure 100j of FIG. 13.

As shown in FIG. 18A, there are first region 10 and the second region 20. The S/D contact structure 162 is formed in the first region 10, and the S/D contact structure 162′ is formed in the second region 20. The semiconductor structure in the first region 10 may be NMOS, and the semiconductor structure formed in the second region 20 may be PMOS.

In some embodiments, the width W_{B5′} of the back side contact structure 178 in the second region 20 is smaller than the width W_{B5} of the back side contact structure 178 in the first region 10. In some embodiments, the depth of back side contact structure 178 in the second region 20 is smaller than the depth of the back side contact structure 178 in the first region 10.

FIG. 18B illustrates a cross-sectional view of the semiconductor structure 100m, in accordance with some embodiments. The semiconductor structure 100m of FIG. 18B includes elements that are similar to, or the same as, elements of the semiconductor structure 100j of FIG. 13.

In some embodiments, the width W_{B2′} of the back side contact structure 178 in the second region 20 may be smaller than the width W_{B2} of the back side contact structure 178 in the first region 10. In some embodiments, the depth of back side contact structure 178 in the second region 20 may be smaller than the depth of the back side contact structure 178 in the first region 10.

In addition, the semiconductor structures 100i to 100m has the front side S/D contact structure 162 and the back side contact structure 178. In some embodiments, the front side S/D contact structure 162 is in direct contact with and electrically connected to the back side contact structure 178.

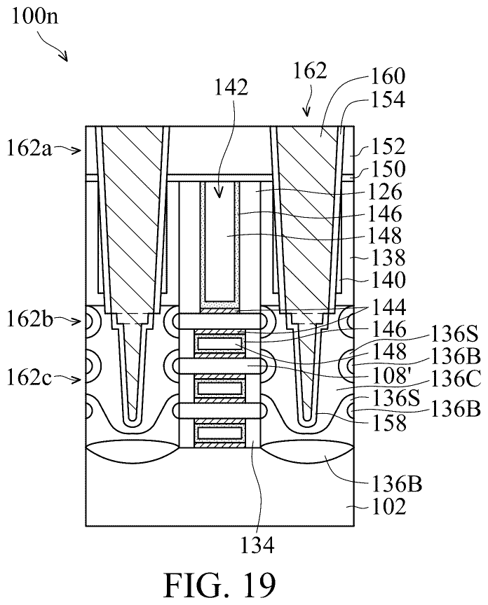

FIG. 19 illustrates a cross-sectional view of a semiconductor structure 100n, in accordance with some embodiments. The semiconductor structure 100n of FIG. 19 includes elements that are similar to, or the same as, elements of the semiconductor structure 100c of FIG. 3, the difference between the FIG. 19 and FIG. 3 is that the S/D structure 136a/136b includes a bottom portion 136B.

The doping concentration of the bottom portion 136B is smaller than the doping concentration of the sidewall portion 136S. In addition, the doping concentration of the bottom portion 136B is smaller than the doping concentration of the central portion 136C.

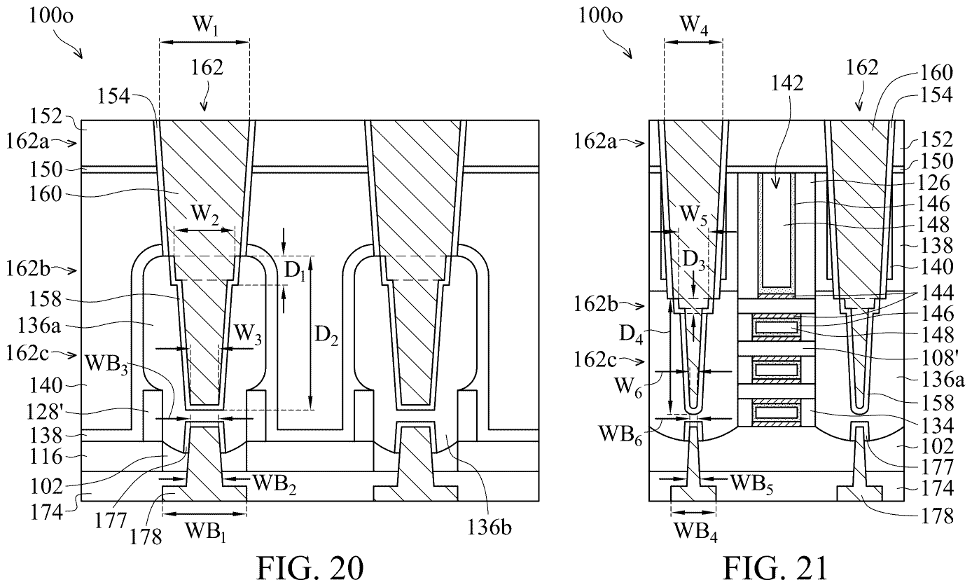

FIG. 20 illustrates a cross-sectional view of a semiconductor structure 100o, in accordance with some embodiments. The semiconductor structure 100o of FIG. 20 includes elements that are similar to, or the same as, elements of the semiconductor structure 100j of FIG. 12, the difference between the FIG. 20 and FIG. 12 is that the metal silicide layer 177 is formed on a portion of the sidewall surface of the back-side contact structure 178.

FIG. 21 illustrates a cross-sectional view of a semiconductor structure 100o, in accordance with some embodiments. The semiconductor structure 100o of FIG. 21 includes elements that are similar to, or the same as, elements of the semiconductor structure 100j of FIG. 13, the difference between the FIG. 21 and FIG. 13 is that the metal silicide layer 177 is formed on a portion of the sidewall surface of the back-side contact structure 178.

Each of the semiconductor structures 100a to 100k, and 100n has a front side S/D contact structure 162 having turning points in sidewall surface. The contact resistance between the S/D contact structure 162 and the S/D contact structure 136a/136b is reduced. In addition, the semiconductor structures 100i to 100m, and 100o has the front side S/D contact structure 162 and the back side contact structure 178. Therefore, the performance of the semiconductor structure is improved.

It should be appreciated that the semiconductor structures 100a to 100o having the front side S/D contact structure 162 and/or the back side contact structure 178 described above may also be applied to FinFET structures, CFET (complementary field-effect transistor), or forksheet, although these are not shown in the figures.

It should be noted that same elements in FIGS. 1A to 21 may be designated by the same numerals and may include similar or the same materials and may be formed by similar or the same processes; therefore such redundant details are omitted in the interest of brevity. In addition, although FIGS. 1A to 21 are described in relation to the method, it will be appreciated that the structures disclosed in FIGS. 1A to 21 are not limited to the method but may stand alone as structures independent of the method. Similarly, although the methods shown in FIGS. 1A to 21 are not limited to the disclosed structures but may stand alone independent of the structures. Furthermore, the nanostructures described above may include nanowires, nanosheets, or another applicable nanostructure in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a gate structure formed over the nanostructures and an S/D structure adjacent to the gate structure. A front side S/D contact structure is formed on front side of the S/D structure, and a portion of the front side S/D contact structure is embedded into the S/D structure. The front side S/D contact structure is formed by two step etching process to form an opening and a T-shaped or a V-shaped trench, and the materials formed in the opening and T-shaped trench or the V-shaped trench. Since the front side S/D contact structure is formed by two step etching process, the aspect ratio is recued to help the filling the contact materials. In addition, the contact area between the front side S/D contact structure and the S/D structure is increased by forming the front side S/D contact structure. The contact resistance between the front side S/D contact structure and the S/D structure is reduced. In addition, the back side contact structure is formed on back side of the S/D structure. The back side contact structure is used to connect to a power rail to reduce the area in the front side interconnect structure. Therefore, the performance of the semiconductor structure is improved.

In some embodiments, a semiconductor structure is provided. The semiconductor structure includes nanostructures formed over a substrate, and a gate structure formed on the nanostructures. The semiconductor structure includes a source/drain (S/D) structure formed adjacent to the gate structure, and a first contact structure formed on the front-side of the S/D structure. The first contact structure includes a top portion with a top width, a middle portion with a middle width, and a bottom portion with a bottom width. The top width is different from the middle width, and the middle width is different from the bottom width.

In some embodiments, a semiconductor structure is provided. The semiconductor structure includes first nanostructures formed over a substrate, and a first gate structure formed on the first nanostructures. The semiconductor structure includes a first source/drain (S/D) structure formed adjacent to the first gate structure and a first contact structure formed on a front-side of the first S/D structure. The first contact structure has a sidewall surface with a turning point. The semiconductor structure includes a second contact structure formed on the back-side of the first S/D structure, and the top surface of the second contact structure is higher than the bottommost surface of the first gate structure.

In some embodiments, a method for forming a semiconductor structure is provided. The method includes forming a fin structure over a substrate, and the fin structure includes first semiconductor material layers and second semiconductor material layers alternately stacked. The method includes removing a portion of the fin structure to form an S/D recess, and forming an S/D structure in the S/D recess. The method includes forming a dielectric layer over the S/D structure, and forming an opening to expose the top surface of the S/D structure. The method includes forming a barrier layer in the opening, and performing a first etching process to form a trench in the S/D structure. The method includes performing a second etching process to enlarge the trench, and forming a first contact structure in the trench. The method includes forming a second contact structure below the first contact structure, and the width of the bottom portion of the first contact structure is smaller than the width of the topmost surface of the second contact structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
nanostructures formed over a substrate;
a gate structure formed on the nanostructures;
a source/drain (S/D) structure formed adjacent to the gate structure; and
a first contact structure formed on a front-side of the S/D structure, wherein the first contact structure comprises a top portion with a top width, a middle portion with a middle width and a bottom portion with a bottom width, the top width is different from the middle width, and the middle width is different from the bottom width.

2. The semiconductor structure as claimed in claim 1, wherein the middle portion of the first contact structure is embedded in the S/D structure, and a greatest width of the middle portion is greater than a smallest width of the top portion.

3. The semiconductor structure as claimed in claim 1, wherein a bottom surface of the first contact structure is lower than a topmost surface of the nanostructures.

4. The semiconductor structure as claimed in claim 1, wherein the first contact structure has a T-shaped structure, and a sidewall surface of the first contact structure has a turning point.

5. The semiconductor structure as claimed in claim 1, further comprising:
a second contact structure formed on a back-side of the S/D structure, wherein a top surface of the second contact structure is higher than a bottommost surface of a gate dielectric layer of the gate structure.

6. The semiconductor structure as claimed in claim 5, further comprising:
a plurality inner spacer layers formed between the gate structure and the S/D structure, wherein the top surface of the second contact structure is higher than a bottommost surface of the inner spacer layers.

7. The semiconductor structure as claimed in claim 6, wherein the second contact structure has a reversed T-shaped structure.

8. The semiconductor structure as claimed in claim 1, further comprising:
a metal silicide layer between the S/D structure and the first contact structure, wherein a sidewall surface of the metal silicide layer has a turning point.

9. The semiconductor structure as claimed in claim 8, further comprising:
a barrier layer formed a sidewall surface of the top portion of the first contact structure, wherein an outermost sidewall surface of the metal silicide layer extends beyond a sidewall surface of the barrier layer.

10. A semiconductor structure, comprising:
first nanostructures formed over a substrate;
a first gate structure formed on the first nanostructures;
a first source/drain (S/D) structure formed adjacent to the first gate structure; and
a first contact structure formed on a front-side of the first S/D structure, wherein the first contact structure has a sidewall surface with a turning point;
a second contact structure formed on a back-side of the first S/D structure, wherein a top surface of the second contact structure is higher than a bottommost surface of the first gate structure.

11. The semiconductor structure as claimed in claim 10, wherein the first S/D structure comprises a sidewall portion and a central portion, the sidewall portion is in direct contact with the first nanostructures, a first doping concentration of the sidewall portion is smaller than a second doping concentration of the central portion, and the first contact structure is separated from the sidewall portion by the central portion.

12. The semiconductor structure as claimed in claim 10, further comprising:
second nanostructures formed over the substrate;
a second gate structure formed on the second nanostructures;
a second S/D structure formed adjacent to the second gate structure; and
a third contact structure formed on a front-side of the second S/D structure, wherein a depth of the third contact structure is smaller than a depth of the first contact structure.

13. The semiconductor structure as claimed in claim 10, wherein the second contact structure has a step-shaped structure.

14. The semiconductor structure as claimed in claim 10, wherein a width of a bottom portion of the first contact structure is smaller than a width of a topmost surface of the second contact structure.

15. The semiconductor structure as claimed in claim 10, further comprising:
a dielectric layer below the substrate, wherein the second contact structure is through the dielectric layer.

16. The semiconductor structure as claimed in claim 10, wherein the second contact structure has a topmost surface and a bottommost surface, and a width of the topmost surface is smaller than a width of the bottommost surface.

17. A method for forming a semiconductor structure, comprising:
forming a fin structure over a substrate, wherein the fin structure comprise first semiconductor material layers and second semiconductor material layers alternately stacked;
removing a portion of the fin structure to form an S/D recess;
forming an S/D structure in the S/D recess;
forming a dielectric layer over the S/D structure;
forming an opening to expose a top surface of the S/D structure;
forming a barrier layer in the opening;
performing a first etching process to form a trench in the S/D structure;
performing a second etching process to enlarge the trench;
forming a first contact structure in the trench; and
forming a second contact structure below the first contact structure, wherein a width of a bottom portion of the first contact structure is smaller a width of a topmost surface of the second contact structure.

18. The method for forming the semiconductor structure as claimed in claim 17, further comprising:
forming a metal silicide layer between the S/D structure and the first contact structure, wherein the metal silicide layer has a step-shaped structure.

19. The method for forming the semiconductor structure as claimed in claim 17, further comprising:
forming a sacrificial layer on the barrier layer in the opening; and
removing the sacrificial layer when performing the second etching process.

20. The method for forming the semiconductor structure as claimed in claim 17, further comprising:
removing a portion of the substrate;
forming a dielectric layer below the S/D structure;
removing a portion of the dielectric layer and a portion of the S/D structure to form a trench; and
forming the second contact structure in the trench.
